(19) United States
(12) Patent Application Publication
(10) Pub. No.: US 2025/0188312 A1
(43) Pub. Date: Jun. 12, 2025

(54) POLY-O-HYDROXYAMIDES COMPRISING NOVEL INDANE BIS-O-AMINOPHENOLS, PHOTOSENSITIVE COMPOSITIONS, DIELECTRIC FILMS, AND BUFFER COATINGS CONTAINING THE SAME

(71) Applicant: Fujifilm Electronic Materials U.S.A., Inc., N. Kingstown, RI (US)

(72) Inventors: Binod B. De, Attleboro, MA (US); William A. Reinerth, Riverside, RI (US)

(21) Appl. No.: 18/960,640

(22) Filed: Nov. 26, 2024

Related U.S. Application Data
(63) Continuation of application No. 63/608,475, filed on Dec. 11, 2023.

(51) Int. Cl. C09D 177/06; C08G 69/40; C08G 73/22

(52) U.S. Cl. CPC C09D 177/06; C08G 69/40; C08G 73/22; C08G 2150/00

(57) ABSTRACT

This disclosure describes highly soluble novel poly-o-hydroxyamides containing indane bis-o-aminophenols, photosensitive compositions containing same, and methods and articles for use thereof.

### CROSS-REFERENCE TO RELATED APPLICATION

The present application claims priority to U.S. Provisional Application Ser. No. 63/608,475, filed on Dec. 11, 2023, the contents of which are hereby incorporated by reference in their entirety.

### BACKGROUND OF THE DISCLOSURE

Dielectric material requirements for semiconductor packaging applications are continuously evolving. The trend in electronic packaging continues to move towards faster processing speeds, increased complexity and higher packing density while maintaining a high level of reliability. As electronic packaging technology advances and chips continue to shrink in size, the demand for innovative and high-performance resin compositions is growing.

### SUMMARY OF THE DISCLOSURE

The disclosure provides dielectric film-forming compositions including polymers comprising at least one indane bis-o-aminophenol compound as a diamine monomer. The dielectric film-forming compositions described herein meet the exceedingly challenging requirements of the microelectronics industry. In some embodiments, the disclosure provides dielectric film-forming compositions comprising poly-o-hydroxyamides comprising at least one indane bis-o-aminophenol compound as a diamine monomer. In certain embodiments, the disclosure provides compositions that include a poly-o-hydroxyamide comprising an indane bis-o-aminophenol monomer of Formula Ia:

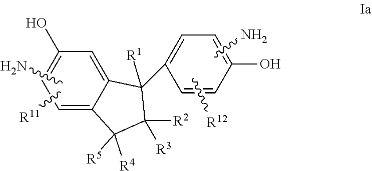

wherein each of R¹, R², R³, R⁴, and R⁵ independently, is a hydrogen atom, a substituted or unsubstituted C₁-C₁₂ alkyl, a partially halogen substituted or fully halogen substituted C₁-C₁₂alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is independently a hydrogen atom, a linear or branched C₁-C₄ alkyl, a partially halogen substituted or fully halogen substituted C₁-C₄ alkyl, a C₅-C₁₂ cycloalkyl, a C₆-C₁₈ aryl, a C₅-C₁₈ heteroaryl group, a C₁-C₄ alkoxy group or a halogen atom.

Poly-o-hydroxyamides of the present disclosure can be used in different photosensitive compositions to provide a positive tone wherein the photosensitive compositions are soluble in an aqueous alkaline solution, can form a fine pattern, and can achieve high resolution. In some embodiments the photosensitivity of the compositions is chemically amplified as described herein.

In some embodiments of the disclosure, there are provided dielectric layers which can be cast from compositions of the disclosure. Dielectric layers of this disclosure can form uniform films which can be developed after exposure to relatively long UV wavelength (e.g., about 365 nm) to form a patterned dielectric film. After photolithographic processing, the patterned layer is converted to a heat resistant polybenzoxazole film by application of additional heating, wherein the patterned cured dielectric film can exhibit desirable properties according to one or more reliability tests. Films formed by the photosensitive compositions have good mechanical properties, even when the compositions are cured at low temperature.

### DETAILED DESCRIPTION OF THE DISCLOSURE

The disclosure provides dielectric film-forming compositions, as well as related processes, dry films, and dielectric films. In some embodiments, the dielectric film-forming compositions described herein include (a) at least one polymer comprising at least one indane bis-o-aminophenol compound as a diamine monomer. In some embodiments, the dielectric film-forming compositions described herein can be photosensitive and/or heat-curable.

In some embodiments there are provided poly-o-hydroxyamides which are suitable for the preparation of photosensitive compositions that meet the exceedingly challenging requirements of the microelectronics industry.

In some embodiments of the disclosure, there are provided poly-o-hydroxyamides represented by general Formula (2)

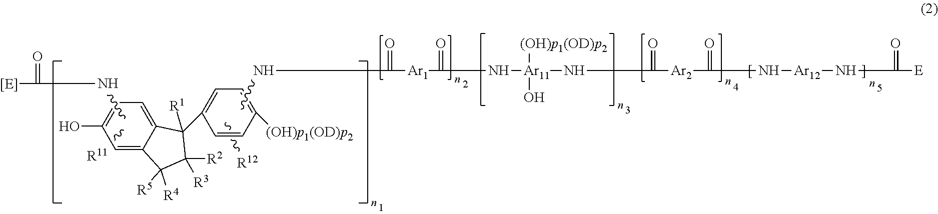

wherein R¹, R², R³, R⁴, R⁵, R¹¹ and R¹² have the same meaning as described above, Ar₁ and Ar₂ are each independently a divalent aromatic, aliphatic, or heterocyclic group, or mixtures thereof; Ar₁₁ and A₁₂ are a divalent aromatic, aliphatic, or heterocyclic group or a siloxane group; E is an end-capping group; n₁ is an integer from 5 to 200; n₃ is an integer from 0 to 200; n₅ is an integer from 0 to 200; n₂ is an integer from 5 to 200 and n₄ is an integer from 0 to 200; p₂ is any positive value of up to about 0.9, p₁ is any value from about 0.1 to about 0.8 with the proviso that (p₁+p₂)=1; D is selected from the group consisting of one of the following moieties wherein R³¹ is selected from a group consisting of hydrogen, halogen, a C₁-C₄ alkyl group, a C₁-C₄ alkoxy group, a substituted or unsubstituted C₄-C₁₈ cycloalkyl:

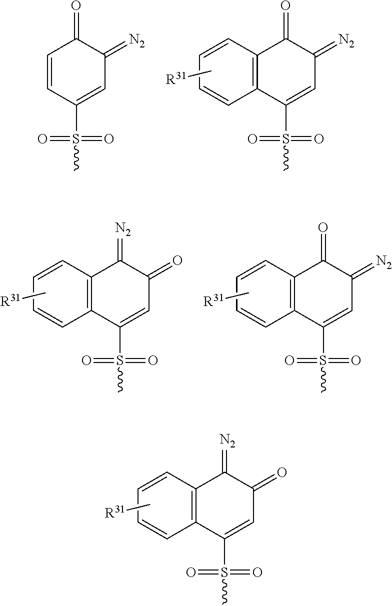

In some embodiments of the disclosure, there are provided poly-o-hydroxyamides represented by general Formula (3)

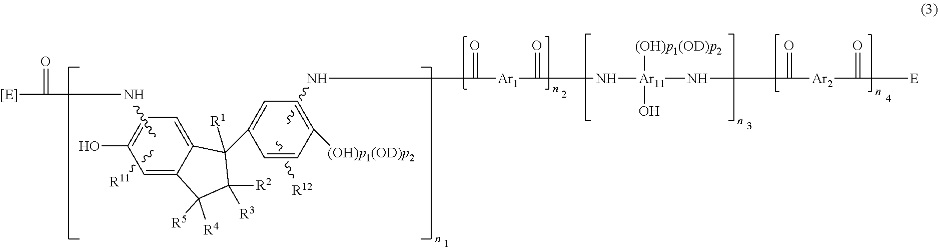

wherein R¹, R², R³, R⁴, R⁵, R¹¹, R¹², Ar₁, Ar₂, Ar₁₁, n¹, n², n³, n⁴, p₁, p₂ and D have the same meaning as described above.

As used herein, “end-capping group” refers to reaction products of amino end groups of poly-o-hydroxyamides with monoanhydride compounds. Monoanhydride compounds, when added to the polymerization system, facilitate termination of a poly-o-hydroxyamide chain, thereby limiting polymer chain growth.

In some embodiments, Ar₁ and Ar₂ include the following moieties:

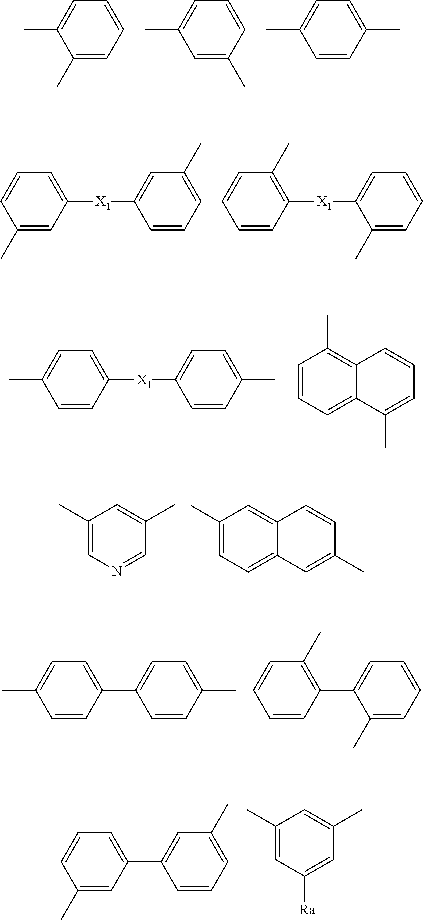

in which X₁ is —C(O)—C(O)—, —C(O)O—, -, a C₅-C₇ cyclic aliphatic group, fluorenyl group, —O—X₃—O, —O—C(O)—X₃—C(O)—O—, —C(O)—O—X₃—O—C(O)— or —(CH₂)ₘ—Si(Z)₂—O—Si(Z)₂—(CH₂)ₘ— where X₃ is a unsubstituted or substituted phenyl, diphenyl sulfone, isopropylidene diphenyl, hexafluoroisopropylidene diphenyl and Z is a H or a C₁-C₆ alkyl group and m is an integer from 1 to 6, Ra is each independently a hydrogen atom, an alkoxy, a fluoroalkoxy, a cycloalkyl, a cycloalkoxy, a cycloalkylsulfonyl, an aryloxy, an alkylaryloxy, an arylsulfonyl, or an alkylarylsulfonyl group.
In some embodiments, the poly-o-hydroxyamide can contain one or more different Ar₁ and Ar₂ groups.

In some embodiments, Ar₁₁ include the following moieties:

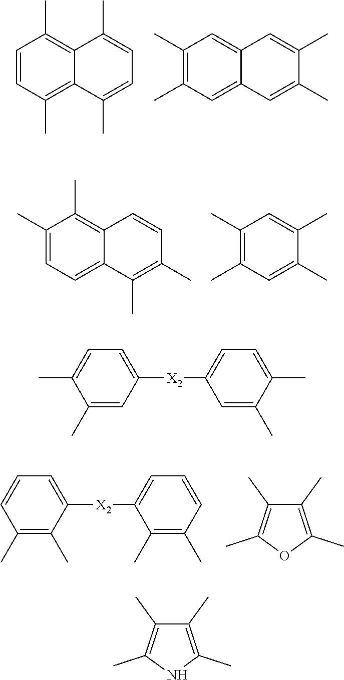

in which X₂ is —O—, —S—, —C(CF₃)₂—, —C(CH₃)₂—, —CH₂—, —SO₂—, —NHCO—, —C(O)—, —C(O)—C(O)—, —C(O)O—, a C₅-C₇ cyclic aliphatic group, fluorenyl group, —O—X₄—O, —O—C(O)—X₄—C(O)—O—, —C(O)—O—X₄—O—C(O)— or —(CH₂)ₘ—Si(Z)₂—O—Si(Z)₂—(CH₂)ₘ—, X₄ is a unsubstituted or substituted phenyl, diphenyl sulfone, isopropylidene diphenyl, hexafluoroisopropylidene diphenyl and Z and m have the same meaning as described above.

Dicarboxylic acid chlorides of the disclosure include, for example, aromatic dicarboxylic acid chlorides such as isophthalic acid chloride, terephthalic acid chloride, 4,4′-hexafluoroisopropylidenedibenzoic acid chloride, 4,4′-biphenyldicarboxylic acid chloric, 4,4′-dicarboxydiphenyl ether chloride, 4,4′-dicarboxytetraphenylsilane chloride, bis(4-carboxyphenyl) sulfone chloride, 2,2-bis(p-carboxyphenyl)propane chloride, 5-tert-butylisophthalic acid chloride, 5-bromoisophthalic acid chloride, 5-fluoroisophthalic acid chloride, 5-chloroisophthalic acid chloride, 2,6-naphthalenedicarboxylic acid chloride, etc.; aliphatic dicarboxylic acid chlorides such as 1,2-cyclobutanedicarboxylic acid chloride, 1,4-cyclohexanedicarboxylic acid chloride, 1,3-cyclopentanedicarboxylic acid chloride, malonic acid chloride, succinic acid chloride adipic acid chloride, sebacoyl chloride, etc. Examples of such diacid chlorides are disclosed in, e.g., U.S. Pat. Nos. 6,143,467 and 7,803,510 wherein, the entire contents of which are hereby incorporated by reference. Any of these dicarboxylic acid chlorides can be used individually or in combination in any suitable ratio to form a poly-o-hydroxyamide described herein.

Examples of indane bis-o-aminophenol compound (Ia) include, but are not limited to:

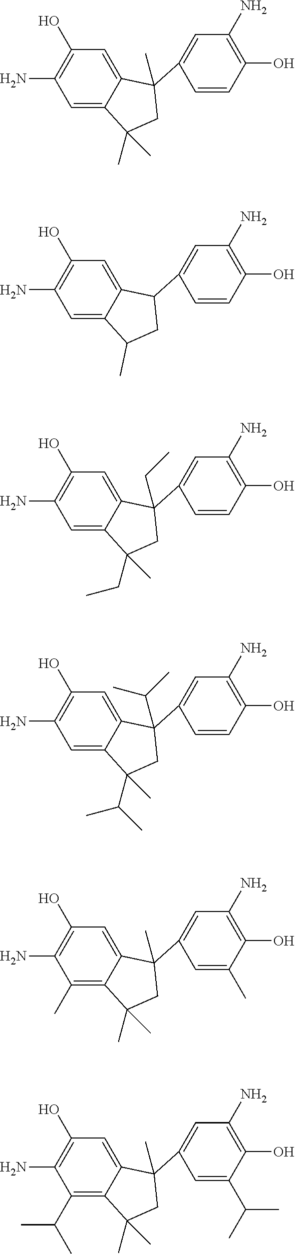 [SMILES: CC1(C)CC(C)(c2ccc(O)c(N)c2)c2cc(O)c(N)cc21 ; CC1CC(c2ccc(O)c(N)c2)c2cc(O)c(N)cc21 ; CCC1(C)CC(CC)(c2ccc(O)c(N)c2)c2cc(O)c(N)cc21 ; CC(C)C1(C)CC(c2ccc(O)c(N)c2)(C(C)C)c2cc(O)c(N)cc21 ; Cc1cc(C2(C)CC(C)(C)c3c2cc(O)c(N)c3C)cc(N)c1O ; CC(C)c1cc(C2(C)CC(C)(C)c3c2cc(O)c(N)c3C(C)C)cc(N)c1O]

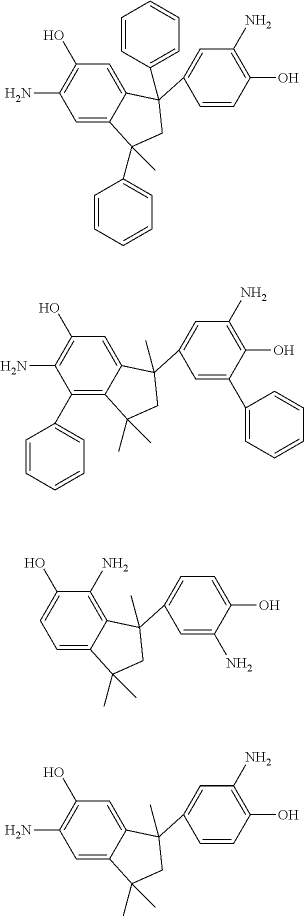 [SMILES: CC1(c2ccccc2)CC(c2ccccc2)(c2ccc(O)c(N)c2)c2cc(O)c(N)cc21 ; CC1(C)CC(C)(c2cc(N)c(O)c(-c3ccccc3)c2)c2cc(O)c(N)c(-c3ccccc3)c21 ; CC1(C)CC(C)(c2ccc(O)c(N)c2)c2c1ccc(O)c2N ; CC1(C)CC(C)(c2ccc(O)c(N)c2)c2cc(O)c(N)cc21]

Exemplary bis-o-hydroxyamines include, but are not limited to, 3,3′-diamino-4,4′-dihydroxybiphenyl, 4,4′-diamino-3,3′-dihydroxybiphenyl, bis(3-amino-4-hydroxyphenyl) propane, bis(4-amino-3-hydroxyphenyl) propane, bis(3-amino-4-hydroxyphenyl) sulfone, bis(4-amino-3-hydroxyphenyl) sulfone, bis(3-amino-4-hydroxyphenyl) hexafluoropropane, bis(4-amino-3-hydroxyphenyl) hexafluoropropane, etc. Examples of such bis-o-hydroxyamines are disclosed in, e.g., U.S. Pat. Nos. 6,143,467; 7,803,510, the entire contents of which are hereby incorporated by reference. Any of these bis-o-hydroxyamines can be used individually or in combination in any suitable ratio to form a poly-o-hydroxyamide described herein.

Examples of suitable diamines containing an Ar12 structure that can be used to prepare of poly-o-hydroxyamide polymer of structure (2) include, but are not limited to, 1-(4-aminophenyl)-1,3,3-trimethylindan-5-amine (alternative names including 4,4′-[1,4-phenylene-bis(1-methylethylidene)]bisaniline, 1-(4-aminophenyl)-1,3,3-trimethyl-2H-inden-5-amine, 1-(4-aminophenyl)-1,3,3-trimethyl-indan-5-amine, and [1-(4-aminophenyl)-1,3,3-trimethyl-indan-5-yl]amine), 1-(4-aminophenyl)-2,3-dihydro-1,3,3-trimethyl-1H-inden-5-amine, 5-amino-6-methyl-1-(3′-amino-4′-methylphenyl)-1,3,3-trimethylindan, 4-amino-6-methyl-1-(3′-amino-4′-methylphenyl)-1,3,3-trimethylindan, 5,7-diamino-1,1-dimethylindan, 4,7-diamino-1,1-dimethylindan, 5,7-diamino-1,1,4-trimethylindan, 5,7-diamino-1,1,6-trimethylindan, 5,7-diamino-1,1-dimethyl-4-ethylindan, p-phenylenediamine, m-phenylenediamine, o-phenylenediamine, 3-methyl-1,2-benzene-diamine, 1,2-diaminoethane, 1,3-diaminopropane, 1,4-diaminobutane, 1,5-diaminopentane, 1,6-diaminohexane, 1,7-diaminoheptane, 1,8-diaminooctane, 1,9-diaminononane, 1,10-diaminodecane, 1,2-diaminocyclohexane, 1,4-diaminocyclohexane, 1,3-cyclohexanebis(methylamine), 5-amino-1,3,3-trimethyl cyclohexanemethanamine, 2,5-diaminobenzotrifluoride, 3,5-diaminobenzotrifluoride, 1,3-diamino-2,4,5,6-tetrafluorobenzene, 4,4′-oxydianiline, 3,4′-oxydianiline, 3,3′-oxydianiline, 3,3′-diaminodiphenylsulfone, 4,4′-diaminodiphenylsulfone, 4,4′-isopropylidenedianiline, 4,4′-diaminodiphenylmethane, 2,2-bis(4-aminophenyl)propane, 4,4′-diaminodiphenyl propane, 4,4′-diaminodiphenyl sulfide, 4,4′-diaminodiphenylsulfone, 4-aminophenyl-3-aminobenzoate, 2,2′-dimethyl-4,4′-diaminobiphenyl, 3,3′-dimethyl-4,4′-diaminobiphenyl, 2,2′-bis(trifluoromethyl) benzidine, 3,3′-bis(trifluoromethyl) benzidine, 2,2-bis[4-(4-aminophenoxyphenyl)] hexafluoropropane, 2,2-bis(3-amino-4-methylphenyl)-hexafluoropropane, 2,2-bis(3-aminophenyl)-1,1,1,3,3,3-hexafluoropropane, 1,3-bis-(4-aminophenoxy)benzene, 1,3-bis-(3-aminophenoxy)benzene, 1,4-bis-(4-aminophenoxy)benzene, 1,4-bis-(3-aminophenoxy)benzene, 1-(4-aminophenoxy)-3-(3-aminophenoxy)benzene, 2,2′-bis-(4-phenoxyaniline)isopropylidene, bis(p-beta-amino-t-butylphenyl)ether, p-bis-2-(2-methyl-4-aminopentyl)benzene, p-bis(1,1-dimethyl-5-aminopentyl)benzene, 3,3′-dimethyl-4,4′-diaminobiphenyl, 4,4′-diaminobenzophenone, 3′-dichlorobenzidine, 2,2-bis[4-(4-aminophenoxy)phenyl]propane, 4,4′-[1,3-phenylenebis(1-methyl-ethylidene)]bisaniline, 4,4′-[1,4-phenylenebis(1-methyl-ethylidene)]bisaniline, 2,2-bis[4-(4-aminophenoxy) phenyl]sulfone, 2,2-bis[4-(3-aminophenoxy)benzene], 1,4-bis(4-aminophenoxy)benzene, 1,3-bis(4-aminophenoxy)benzene, 1,3′-bis(3-aminophenoxy)benzene 4,4′-diamino-2,2′-bis(trifluoromethyl)biphenyl, H-fluorene-2,6-diamine, 4,4′-methylenebis(2,6-diethylaniline), 4,4′-methylenebis(2,6-dimethylaniline), 4,4′-methylenebis(2,6-diisopropylaniline), 4,4′-methylenebis(2,6-dipropylaniline), 4,4′-methylenbis(2,6-di tert-butylaniline), 3,5-diaminobenzoic acid, 3,4-diaminobenzoic acid, bis(aminopropyl)tetramethyldisiloxane (BATMS), bis(aminopropyl)tetraphenyldisiloxane, bis(4-aminophenoxy)dimethylsilane and the like. Any of these diamines can be used individually or in combination in any suitable ratio to form a poly-o-hydroxyamide described herein.

The poly-o-hydroxyamide (Structure 2a) may be synthesized by numerous synthetic procedure variations of those procedures known to those skilled in the art.

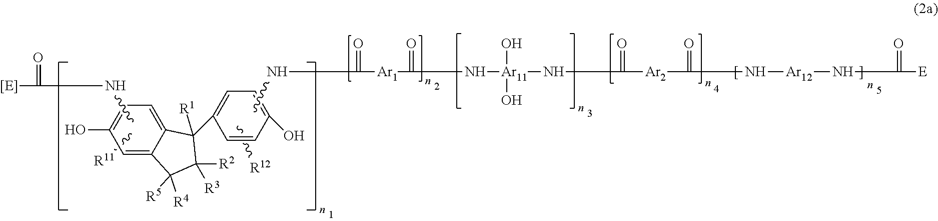

wherein R¹, R², R³, R⁴, R⁵, R¹¹, R¹², Ar₁, Ar₂, A₁₁, Ar₁₂, n₁, n₂, n₃, n₄ and n₅ have the same meaning as described above.

In general, the synthetic procedure brings one or more bis-o-hydroxyamine in contact with one or more diacid chloride in the presence of a solvent and optionally a base or mixture thereof suitable to dissolve the monomers, and preferably the resultant poly-o-hydroxyamide. Examples of suitable base include, but are not limited to, pyridine, triethylamine, tripropylamine, tributylamine, dicyclohexylmethylamine, 2,6-lutidine, 3,5-lutidine, picoline, 4-dimethylaminopyridine (DMAP) and the like. If used, the basic catalyst employed can be the same as or different from the basic catalyst employed in the end-capping reaction.

In some embodiments, to prepare a poly-o-hydroxyamide, the bis-o-hydroxyamine component and diacid chloride component are charged into a reaction vessel by a method of gradually charging one of the components in the form of solid or solution into a solution of the other component (complete dissolution of all materials might not occur) or a method of charging both the components at the same time. The molar ratio of bis-o-hydroxyamine component(s) to diacid chloride component(s) is preferably from between 1.01 to 1.50. More preferably, a molar ratio of diamine to diacid chloride of about 1.05 to 1.30 is employed. Generally, the reaction is carried out at about −15° C. to about 50° C. for about 1 to about 48 hours. Note that when the molar ratio of bis-o-hydroxyamine component(s) to diacid chloride component(s) is greater than 1.00, the resulting species is an amino-terminated poly-o-hydroxyamide, which can be further reacted with an end-capping monomer to form an end-capped polymer.

Suitable polymerization solvents useful in the present invention include, but are not limited to, N-methyl-2-pyrrolidone, N,N-dimethylformamide, dimethylsulfoxide, gamma-butyrolactone, N, N-dimethylacetamide, tetramethylene sulfone, p-chlorophenol, m-cresol, diethyleneglycol methyl ether, methyl-3-methoxypropionate, ethyl-3-ethoxypropionate, cyclohexanone, propylene glycol monomethyl ether acetate, and 2-chloro-4-hydroxytoluene. These solvents may be used singly or in combination of two or more. Of these solvents, preferred are N-methyl-2-pyrrolidone, gamma-butyrolactone and N, N-dimethylacetamide, with N-methyl-2-pyrrolidone being more preferred. In some embodiments, a poor solvent for the poly-o-hydroxyamide may be used in combination with these solvents in such an amount to not allow the poly-o-hydroxyamide to precipitate. Examples of such a poor solvent include hexane, heptane, benzene, toluene, xylene, chlorobenzene and o-dichlorobenzene. The amount of the poor solvent to be used is preferably 50 percent by weight or less (inclusive of zero) based on the total amount of the solvents. The poly-o-hydroxyamide thus produced may be isolated by precipitation into a non-solvent or a poor solvent and collected by filtration.

The second step of the synthetic process towards the polymer of Structure 2 mentioned above is to end-cap the poly-o-hydroxyamide synthesized in the first step.

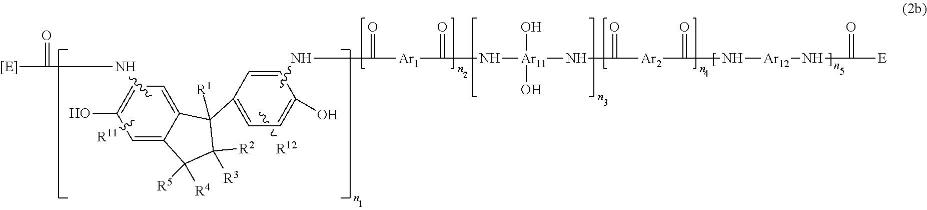

wherein R¹, R², R³, R⁴, R⁵, R¹¹, R¹², Ar₁, Ar₂, A₁₁, Ar₁₂, n₁, n₂, n₃, n₄, n₅ and E have the same meaning as described above.

In some embodiments, the second step can be carried out by reacting an amino-terminated poly-o-hydroxyamide of Structure 2a with a monoanhydride to yield an end-capped poly-o-hydroxyamide of Structure 2b In some embodiments, the end-capped poly-o-hydroxyamide thus formed can be used for further reaction without isolation. Monoanhydrides contemplate for use in this aspect of the disclosure include, for example, aliphatic acid anhydrides such as acetic anhydride, trifluoroacetic anhydride, pivalic anhydride, or cyclic anhydrides such as 1,1-cyclopentanediacetic anhydride, succinic anhydride, maleic anhydride, exo-3,6-epoxy-1,2,3,6-tetrahydrophthalic anhydride, cis-1,2-cyclohexanedicarboxylic anhydride, cis-4-cyclohexene-1,2-dicarboxylic anhydride, 5-norbornene-2,3-dicarboxylic anhydride, bicyclo[2.2.1]hept-5-ene-2,3-dicarboxylic anhydride and the like. Further examples of end-capping groups are disclosed in, e.g., U.S. Pat. No. 9,695,284, the entire contents of which are hereby incorporated by reference.

In some embodiments, the second step can be carried out by reacting an amino-terminated poly-o-hydroxyamide and unreacted diamine monomers with a monoanhydride to yield an end-capped poly-o-hydroxyamide and adducts wherein an amine value of poly-o-hydroxyamide polymer precursor is about 0.0010 to 0.0300 mmol/g. When the amine value is higher than these numerical values, the amine group will interfere with decomposition process of diazoquinone residues.

In some embodiments, in the third reaction step, the poly-o-hydroxyamide is reacted with about 1 percent to about 50 percent mole percent (based on the number of OH groups from the monomer) in a diazoquinone compound (DCI) in the presence of a base to yield the poly-o-hydroxyamide according to reaction:

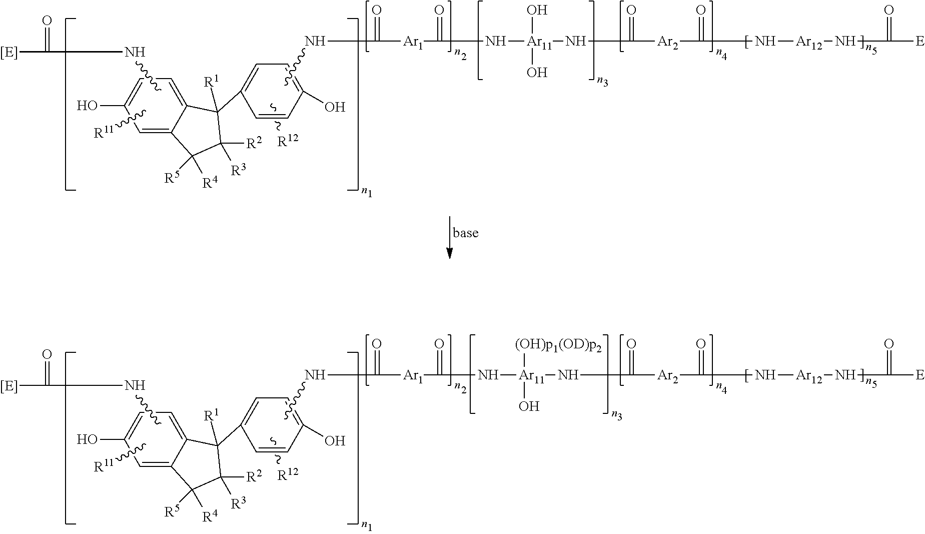

Suitable DCI compounds include:

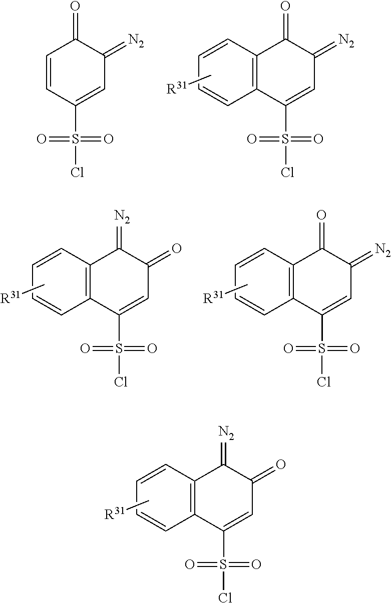

The weight average molecular weight (Mw) of poly-o-hydroxyamide can be determined by such standard methods as membrane osmometry or gel permeation chromatography as described, for example, in Jan Rabek, Experimental Methods in Polymer Chemistry, John Wiley & Sons, New York, 1983.

Suitable weight average molecular weight (Mw) ranges for the poly-o-hydroxyamide of Structure 2 range from about 1,000 g/mol to about 80,000 g/mol. Preferred molecular weight ranges may depend on the particular product application, solvent employed, and method of applying to the underlying substrate. For example, suitable weight average molecular weight values for coating applications can be at least about 1,000 g/mol (e.g., at least about 9,000 g/mol, at least about 12,000 g/mol, at least about 15,000 g/mol, at least about 20,000 g/mol, at least about 25,000 g/mol, or at least about 35,000 g/mol) and/or can be at most about 50,000 g/mol (e.g., at most about 40,000 g/mol, at most about 35,000 g/mol, at most about 30,000 g/mol, at most about 25,000 g/mol, at most about 20,000 g/mol, at most about 15,000 g/mol, at most about 12,000 g/mol.

Wherever the term “solvent(s)” is used, if not specifically stated, it refers to either a single organic solvent or a combination of two or more organic solvents. The purification or isolation of poly-o-hydroxyamides may be accomplished by numerous procedures known to those skilled in the art. The solution isolation procedure of poly-o-hydroxyamide polymers is an efficient, environmentally friendly processes to produce poly-o-hydroxyamide polymers having enhanced purity.

The purification process can include (a) providing an organic solution containing a poly-o-hydroxyamide in at least one polar, aprotic polymerization solvent; (b) adding at least one purification solvent to the organic solution to form a diluted organic solution, the at least one purification solvent is less polar than the at least one polymerization solvent and has a lower water solubility than the at least one polymerization solvent at 25° C.; (c) washing the diluted organic solution with acidified aqueous solution to obtain a washed organic solution; (d) removing at least a portion of the at least one purification solvent in the washed organic solution to obtain a solution containing a purified poly-o-hydroxyamide.

Without wishing to be bound by theory, it is believed that the two key functions of the purification solvent(s) are to (1) maintain the poly-o-hydroxyamide polymer in solution and (2) form a biphasic mixture with water and/or an aqueous solution containing an additive. In the context of this disclosure, biphasic mixture refers to a mixture containing two distinct and separate phases (e.g., two distinct liquid phases).

In some embodiments, the purification solvent(s) can include an ester, an ether, a ketone, a hydrocarbon optionally substituted by at least one chloride. Examples of suitable purification solvent(s) include, but are not limited to, methyl acetate, ethyl acetate, n-propyl acetate, isopropyl acetate, n-butyl acetate, isobutyl acetate, sec-butyl acetate, cyclohexyl acetate, ethyl lactate, propylene glycol monomethyl ether acetate (PGMEA), tetrahydrofurfuryl acetate, propyl formate, butyl formate, isobutyl formate, pentyl formate, epsilon-caprolactone, diethyl ether, dipropyl ether, dibutyl ether, dicyclohexyl ether, cyclopentyl methyl ether, methyl tert-butyl ether, ethyl tert-butyl ether, anisole, phenyl ethyl ether, diphenyl ether, 1,2-dimethoxypropane, 1,2-dimethoxyethane, 2-butanone, 2-pentanone, 3-pentanone, methyl isobutyl ketone, ethyl isobutyl ketone, methyl isopropyl ketone, cyclopentanone, cyclohexanone, acetophenone, isophorone, mesityl oxide, benzene, toluene, xylene, ethyl benzene, chlorobenzene, 1,2-dichlorobenzene, α,α,α-trifluorotoluene, pentane, hexane, heptane, octane, cyclohexane, methylcyclohexane, cyclohexene, and mixtures thereof.

Depending on the solubility characteristics of the poly-o-hydroxyamide polymer, the purification solvent(s) may be used as the sole solvent(s) in the dilution/purification step. However, in some embodiments, in addition to the purification solvent(s), a purification co-solvent(s) may be employed. Purification co-solvents are organic solvents that have a higher (e.g., significantly higher) solubility in water at 25° C. than the purification solvent(s). In general, a purification co-solvent(s) is not used alone but is used in combination with one or more purification solvent(s). In some embodiments, the purification solvents can be water immiscible solvents.

Examples of suitable purification co-solvents include, but are not limited to, acetone, gamma-butyrolactone (GBL), furan, tetrahydrofuran, methyl tetrahydrofuran, tetrahydrofurfuryl methyl ether, 1,4-dioxane, and mixtures thereof. In some embodiments, the purification co-solvents can be water miscible solvents.

When an aqueous solution containing an additive is employed in this step, this solution can contain an acid, a base, or additional components, such as chelating agents, in a sufficient concentration to enhance the purity of the poly-o-hydroxyamide polymer by removal of impurities (e.g., polymerization by-products). The concentration of the acid, the base, or other additives in this aqueous solution may range from at least about 0.1 wt % (e.g. at least about 0.3 wt %, at least about 0.5 wt %, or at least about 1 wt %) to at most about 10 wt % (e.g. at most about 8 wt %, at most about 7 wt %, or at most about 5 wt %).

In some embodiments, the washing step can include adding water or an aqueous solution to the diluted organic solution obtained in the dilution step above. In such embodiments, the washing step can include forming a mixture having an organic phase and an aqueous phase (e.g., by allowing the organic phase and the aqueous phase to separate from each other). The washing step can further include removing the aqueous phase. In general, washing the diluted solution can substantially remove the at least one polymerization solvent or another impurity in the diluted organic solution.

In order to improve the effectiveness of the washing step, the diluted organic solution containing a poly-o-hydroxyamide polymer and the aqueous washing medium (e.g., water or an aqueous solution) can be mixed by agitation. This agitation may take the form of stirring, shaking, inverting or any other method which permits effective mixing of the organic and aqueous phases.

Following mixing, the mixture can be allowed to stand undisturbed until two distinct and separate phases are formed. Upon the formation of distinct and separate phases, the aqueous phase can be removed and discarded to remove impurities (e.g., a polymerization solvent). In some embodiments, the number of aqueous washes is from one to five (i.e., one, two, three, four or five).

A wide range of agitation rate, time, temperature, and separation conditions may be employed. Without wishing to be bound by theory, it is believed that an essential aspect of this step is to ensure sufficient mixing of the mixtures to extract significant amounts of the polymerization solvent(s) and other impurities into the aqueous phase followed by phase separation. These conditions may vary depending on the vessel employed for the mixing and separation. In some embodiments, the agitation time is from about 1 minute to about 24 hours (e.g., from about 10 minutes to about 6 hours). In some embodiments, the agitation temperature is from about 10° C. to about 40° C. (e.g., from about 15° C. to about 30° C.). In some embodiments, the separation time is from about 10 minutes to about 24 hours (e.g., from about 15 minutes to about 12 hours). In some embodiments, the separation temperature is from about 10° C. to about 40° C. (e.g., from about 15° C. to about 30° C.).

In some embodiments, when a poly-o-hydroxyamide polymer is being formed and purified, the amount of residual polymerization solvent(s) remaining after the final aqueous washing is at most about 1 wt % (e.g., at most about 0.5 wt %) of the weight of the poly-o-hydroxyamide polymer.

After the organic solution containing a poly-o-hydroxyamide polymer is washed by an aqueous medium (e.g., water), at least a portion (e.g., substantially all) of the purification solvent(s) in the organic solution can be removed or exchanged for at least one isolation solvent(s) to obtain a solution containing a purified poly-o-hydroxyamide polymer (i.e., a purified polymer solution).

In some embodiments, a solution containing a purified poly-o-hydroxyamide polymer (i.e., a purified polymer solution) is treated with ion exchange resin (acidic, basic or mixture of acidic and basic ion exchange resin) to remove trace amount acid or base from purified polymer solution. In certain embodiments, the ion exchanged purified poly-o-hydroxyamide solution is filtered through a filter media (pad, cartridge) to remove if any gel present in the polymer solution.

In some embodiments, at least a portion (e.g., substantially all) of the purification solvent(s) (and essentially all residual water) in the purified polymer solution can be solvent exchanged for an isolation solvent(s). In some embodiments, the isolation solvent(s) is a solvent or combination of two or more solvents whose boiling point is equal to or greater than the purification solvent(s). In certain embodiments, the isolation solvent(s) can be the same as the purification solvent(s) or polymerization solvent(s). In other embodiments, the isolation solvent(s) can be different from the purification solvent(s) or polymerization solvent(s). In some embodiments, the isolation solvent(s) are compatible with various coating and application methods employed in many industrial applications.

In some embodiments, the isolation solvent(s) can include a ketone, an ester, a hydrocarbon, a sulfoxide, an ether, or a mixture thereof. Examples of suitable isolation solvent(s) include, but are not limited to, methyl ethyl ketone (MEK), methyl isobutyl ketone (MIBK), 2-heptanone, cyclopentanone, cyclohexanone, xylene, gamma-butyrolactone, dimethylsulfoxide, propylene glycol monomethyl ether acetate (PGMEA), propylene glycol monomethyl ether (PGME), ethyl lactate (EL) and mixtures thereof.

In some embodiments, the isolation solvent(s) can be first added to the washed, purified organic solution containing a poly-o-hydroxyamide polymer. In such embodiments, the purification solvent(s) can then be removed by evaporation or distillation. In some embodiments, the amount of residual purification solvent(s) remaining after this step can be at most about 2 wt % (e.g., at most about 1 wt %) of the weight of the poly-o-hydroxyamide polymer. Without wishing to be bound by theory, it is believed that adding an isolation solvent(s) have a boiling point higher than that of the purification solvent(s) can facilitate the removal of the purification solvent(s) during distillation.

Without wishing to be bound by theory, it is believed that, in addition to exchanging the purification solvent(s) for the isolation solvent(s), this step also serves to dry the final polymer solution by removing residual water along with the purification solvent(s) (e.g., through distillation).

In some embodiments, after at least a portion (e.g., substantially all) of the purification solvent(s) is exchanged for the isolation solvent(s), the solution containing the poly-o-hydroxyamide polymer can be concentrated to form a solution suitable for coating on a substrate.

The distillation conditions can be any temperature and pressure under which the polymer is stable that will produce the desired end result. In some embodiments, the distillation temperature is from about 20° C. to about 70° C. (e.g., from about 25° C. to about 45° C.). In some embodiments, the distillation pressure is from about 760 Torr to about 0.1 Torr (e.g., from about 100 Torr to about 0.1 Torr). While the process detailed above leads to poly-o-hydroxyamide polymers of enhanced purity, it should be noted that additional process steps including, but not limited to, ion exchange and filtration may be included before and/or after steps 3 and 4 in this process.

In some embodiments, this disclosure features a purified poly-o-hydroxyamide polymer solution obtained from the process above. In some embodiments, a purified poly-o-hydroxyamide polymer can be isolated from the purified polymer solution obtained above by any suitable method known in the art (e.g., by precipitation or removal of solvents via distillation).

In one embodiment, the poly-o-hydroxyamide polymers of enhanced purity produced using the process of the present disclosure can be incorporated into compositions (e.g., film-forming compositions, thermally curable compositions, photosensitive compositions).

The polybenzoxazole precursor in the present invention has a hydroxyl group concentration of 3.35 mol/Kg or more when it does not contain a fluoride atom. When it is 4.0-10.0 mol/Kg and contains a fluoride atom, the hydroxyl group concentration is not less than 2.00 mol/Kg, preferably 3.0-10.0 mol/Kg. When the hydroxyl concentration is lower than these numerical values, there is a disadvantage that the poly-o-hydroxyamide polymers is not sufficiently dissolved in an alkaline aqueous solution.

In another embodiment, the unexposed photosensitive film having poly-o-hydroxyamide (I) has dissolution rate of less than 0.05 um/sec in an aqueous alkaline solution with a pH greater than 8.0. In some embodiment, the unexposed photosensitive film having poly-o-hydroxyamide (I) has a dissolution rate of less than 0.01 um/sec in a 2.38 percent tetramethylammonium hydroxide aqueous solution.

In some embodiments, the indane bis-o-aminophenols of the disclosure enable the preparation of soluble poly-o-hydroxyamides. During photolithographic processing, the aqueous base solubility of the poly-o-hydroxyamides present in photosensitive compositions is inhibited, and then re-established by use of at least one photoactive compound (PAC). In some embodiments, diazoquinone PACs are used to inhibit solubility of poly-o-hydroxyamides in an aqueous base. After exposure to light, the diazoquinone compound undergoes photolysis and converts to indenecarboxylic acid, which promotes aqueous base solubility of the poly-o-hydroxyamides. In some embodiments, diazonaphthoquinone PACs are used as dissolution inhibitor. Intermediates generated by capping of an aromatic hydroxyl group of a poly-o-hydroxyamide with a PAC are known as capped poly-o-hydroxyamides. Examples of such diazonaphthoquinone PAC are listed below, where D has the same meaning above. Examples of such diazonaphthoquinone PACs are also disclosed in U.S. Pat. No. 7,803,510 wherein, the entire contents of which are hereby incorporated by reference.

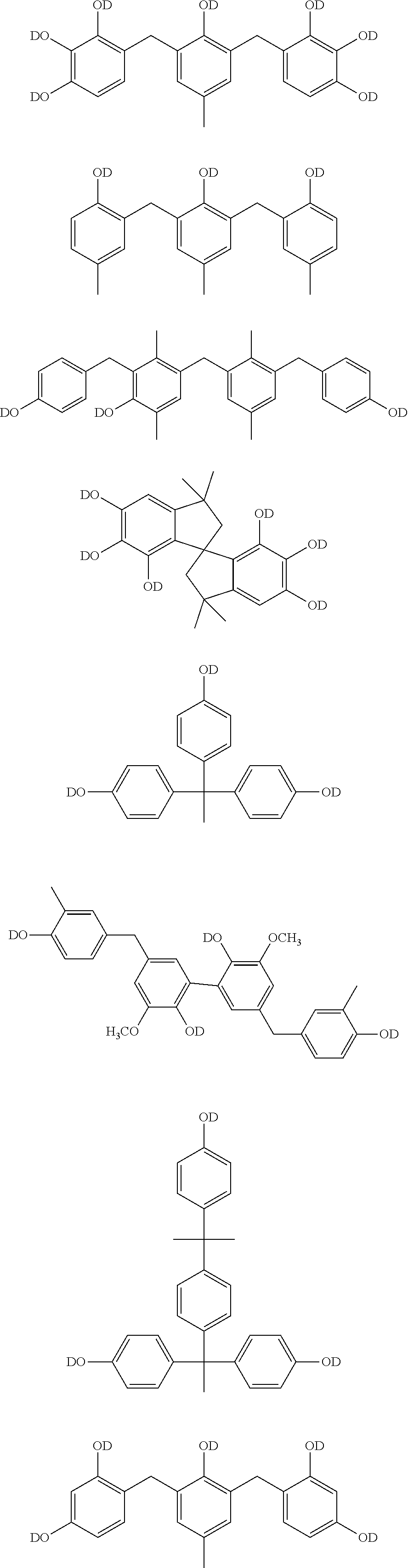

Capped poly-o-hydroxyamides can be prepared with one or more diazoquinone compounds, one or more dihydropyridines, or mixtures thereof. The amount of diazoquinone compound used in this composition is from about 1 weight percent to 20 weight percent of the total weight of the composition, from about 2 weight percent to about 10 weight percent, and from about 3 weight percent to about 5 weight percent. The amount of dihydropyridine compound used in this composition is from about 1 weight percent to 20 weight percent of the total weight of the composition from about 2 weight percent to about 10 weight percent, from about 3 weight percent to about 5 weight percent. If both the diazoquinone compound and the dihydropyridine compound are used, the amount of the diazoquinone compound and the dihydropyridine in this composition is from about 1 weight percent to 20 weight percent of the total weight of the composition, from about 2 weight percent to about 10 weight percent, and, from about 3 weight percent to about 5 weight percent.

In some embodiments, crosslinkers are used in the compositions of the disclosure. Any suitable amino or phenolic crosslinking agent may be used in the present application such as methylolated and/or methylolated and etherified guanamines, methylolated and/or methylolated and etherified melamines and the like. These types of crosslinking agents behave as latent crosslinkers which generate intermediates in the presence of heat, or in the presence of thermogenerated or photogenerated acids. These reactive intermediates react either with themselves (to form a crosslinked interpenetrating network (IPN)) or react with hydroxy functional groups of poly-hydroxyamides forming crosslinked polymeric materials.

Any suitable amino or phenolic crosslinking agent may be used in the present application such as methylolated and/or methylolated and etherified guanamines, methylolated and/or methylolated and etherified melamines and the like. Examples of suitable melamine cross-linking agents are methoxyalkylmelamines such as hexamethoxymethylmelamine, trimethoxymethylmelamine, hexamethoxyethylmelamine, tetramethoxyethylmelamine, hexamethoxypropylmelamine, pentamethoxypropylmelamine, and the like. In some embodiments the melamine cross-linking agent is hexamethoxymethylmelamine. In some embodiments aminocrosslinking agents are MW100LM melamine crosslinker from Sanwa Chemical Co. Ltd., Kanaxawa-ken, Japan; Cymel 303, Cymel 1171, and Powderlink 1174 from Cytec Industries, West Patterson, New Jersey. Examples of suitable phenolic crosslinking agents are disclosed in U.S. Pat. Nos. 5,488,182 and 6,777,161 and US Patent application 2005/0238997. Specific examples of hydroxymethyl-substituted polyfunctional phenols used as crosslinker precursor are 4,4′-[1,4-phenylenebis(methylidene)]bis(3,5-dihydroxymethyl phenol), 4,4′-[1,4-phenylenebis(1-ethylidene)]bis(3,5-dihydroxymethyl phenol), 4,4′-[1,4-phenylenebis(1-propylidene)]bis(3,5-dihydroxymethyl phenol), 4,4′-[1,4-phenylenebis(1-butylidene)]bis(3,5-dihydroxymethyl phenol), 4,4′-[1,4-phenylenebis(1-pentylidene)]bis (3,5-dihydroxymethyl phenol), 4,4′-[1,4-phenylenebis(1-methyl ethylidene)]bis(3,5-dihydroxymethyl phenol), 4,4′-[1,4-phenylenebis(1-ethyl propylidene)]bis(3,5-dihydroxymethyl phenol), 4,4′-[1,4-phenylenebis(1-propyl butylidene)]bis(3,5-dihydroxymethyl phenol), 4,4′-[1,4-phenylenebis(1-butyl pentylidene)]bis(3,5-dihydroxymethyl phenol), 4,4′-[1,3-phenylenebis(methylidene)]bis(3,5-dihydroxymethyl phenol), 4,4′-[1,3-phenylenebis(1-methyl ethylidene)]his (3,5-dihydroxymethyl phenol), 4,4′-[1,3-phenylenebis(1-ethyl propylidene)]bis(3,5-dihydroxymethyl phenol), 4,4′-[1,3-phenylenebis(1-propyl butylidene)]bis(3,5-dihydroxymethyl phenol) and 4,4′-[1,3-phenylenebis(1-butyl pentylidene)]bis(3,5-dihydroxymethyl phenol) are given as specific examples of hydroxymethyl-substituted polyfunctional phenols as crosslinker precursor.

More examples of crosslinking agents are given below where G is a methylol or etherified methylolated group. Crosslinkers employed in this disclosure can be purchased commercially, or prepared by hydroxymethylation or alkoxymethylation of the corresponding phenols using standard techniques known to those skilled in the art.

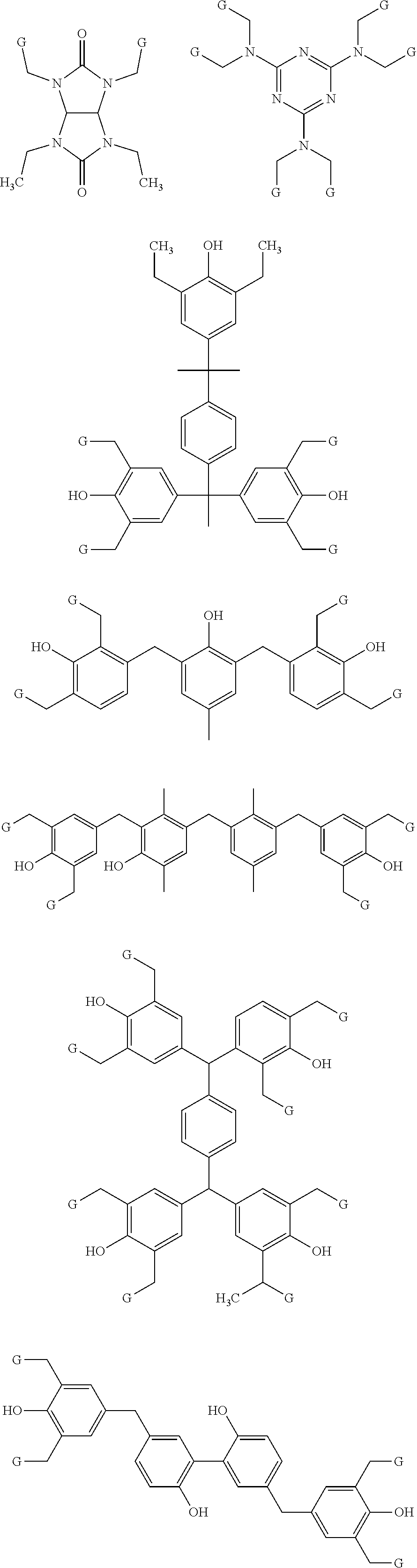

Further examples of crosslinking agents are described in, e.g., U.S. Pat. Nos. 5,488,182 and 6,777,161 and 8,153,346; the contents of which are hereby incorporated by reference.

Uncapped or capped poly-o-hydroxyamides can be formulated with one or more amino or phenolic crosslinking agents, or mixtures thereof. The amount of amino or phenolic crosslinking agents used is from about 1 weight percent to about 25 weight percent of the total weight of the composition, from about 2 weight percent to about 15 weight percent, from about 3 weight percent to about 10 weight percent.

In some embodiments, the amount of the poly-o-hydroxyamide resin or is at least about 0.1 wt. % (e.g., at least about 0.5 wt. %, at least about 1 wt %, at least about 2 wt %, at least about 5 wt %, at least about 10 wt %, at least about 15 wt %, or at least about 20 wt %) and/or at most or about 55 wt % (e.g., at most about 50 wt %, at most about 45 wt %, at most about 40 wt %, at most about 35 wt %, at most about 30 wt %, at most about 25 wt %, at most about 20 wt %, at most about 15 wt %, or at most about 10 wt %) of the solid weight of the dielectric film forming compositions described herein.

In some embodiments, the amount of a photosensitizer is from at least about 0.01 wt % (e.g., at least about 0.05 wt %, at least about 0.1 wt %, or at least about 0.5 wt %) to at most about 1 wt % (e.g., at most about 0.8 wt %, at most about 0.6 wt %, at most about 0.5 wt %, at most about 0.4 wt %, at most about 0.2 wt % of the solid weight of a dielectric film forming composition described herein.

In some embodiments, the dielectric film forming compositions described herein can include at least one (e.g., two, three, or four) photosensitizers, where the photosensitizer can absorb light in the wavelength range of from about 150 nm to about 600 nm (e.g., at about 405 nm). Examples of suitable photosensitizers that can be used in the dielectric film forming compositions of the disclosure include benzophenone compounds, thioxanthone compounds, anthraquinone compounds, anthracene compounds, coumarine compounds, and mixtures thereof.

Some examples of photosensitizers include, but are not limited to, 9-methylanthracene, 9,10-dibutoxyanthracene, 9,10-diethoxyanthracene, anthracenemethanol, acenaphthylene, thioxanthone, methyl-2-naphthyl ketone, 4-acetylbiphenyl, and 1,2-benzofluorene. Examples of other photosensitizers are disclosed in, e.g., U.S. Application Publication No. 2022/0171285, the entire contents of which are hereby incorporated by reference. In some embodiments, the acyl germanium compounds described herein can serve as a photosensitizer.

In some embodiments, the dielectric film forming compositions described herein can further include one or a mixture (e.g., two, three, or four) of organic solvents. In some embodiments, the solvents are selected from group consisting of alkylene carbonates, lactones, cycloketones, linear ketones, alkyl esters; alkyl ester alcohol, alkyl ether alcohols, alkyl ether ester, glycol ester; glycol ether, cyclic ether, pyrrolidone, and dialkylsulfoxide and their mixture thereof. Examples of organic solvents suitable for the dielectric film forming compositions described herein include, but are not limited to, alkylene carbonates such as ethylene carbonate, propylene carbonate, butylene carbonate, and glycerine carbonate; lactones such as gamma-butyrolactone, ε-caprolactone, γ-caprolactone and γ-valerolactone; cycloketones such as cyclopentanone and cyclohexanone; linear ketones such as methyl ethyl ketone (MEK) and methyl isobutyl ketone (MIBK); esters such as n-butyl acetate; ester alcohol such as ethyl lactate; ether alcohols such as tetrahydrofurfuryl alcohol; ether ester such as (tetrahydrofuran-2-yl)methyl acetate, methyl-3-methoxypropionate, ethyl-3-ethoxypropionate and 3-methoxy butyl acetate; glycol esters such as propylene glycol methyl ether acetate; glycol ethers such as propylene glycol methyl ether (PGME); cyclic ethers such as tetrahydrofuran (THF); pyrrolidones such as N-methyl-2-pyrrolidone, N-ethyl-2-pyrrolidone or N-butyl-2-pyrrolidone or TamiSolve™ NxG; and dialkyl sulfoxide such as dimethyl sulfoxide.

In some embodiments, the total amount of the solvent is at least about 20 wt. % (e.g., at least about 25 wt. %, at least about 30 wt. %, at least about 35 wt. %, at least about 40 wt. %, at least about 45 wt. %, at least about 50 wt. %, at least about 55 wt. %, at least about 60 wt. %, or at least about 65 wt. %) and/or at most about 98 wt. % (e.g., at most about 95 wt. %, at most about 90 wt. %, at most about 85 wt. %, at most about 80 wt. %, at most about 75 wt. %, at most about 70 wt. %, or at most about 60 wt. %) of the total weight of the dielectric film forming compositions described herein.

In some embodiments, the dielectric film forming compositions described herein optionally includes at least one (e.g., two, three, or four) filler (such as an inorganic filler or an inorganic particle). In some embodiments, the inorganic filler is selected from the group consisting of silica, alumina, titania, zirconia, hafnium oxide, CdSe, CdS, CdTe, CuO, zinc oxide, lanthanum oxide, niobium oxide, tungsten oxide, strontium oxide, calcium titanium oxide, sodium titanate, barium sulfate, barium titanate, barium zirconate, and potassium niobate. The inorganic fillers are in a granular form of an average size of about 0.1-2.0 microns. In some embodiments, the filler is an inorganic particle containing a ferromagnetic material. Suitable ferromagnetic materials include elemental metals (such as iron, nickel, and cobalt) or their oxides, sulfides and oxyhydroxides, and intermetallics compounds such as Awaruite (Ni₃Fe), Wairaruite (CoFe), Co₁₇Sm₂, and Nd₂Fe₁₄B.

In some embodiments, the amount of the inorganic filler (e.g., silica filler) is at least about 1 wt. % (e.g., at least about 2 wt. %, at least about 5 wt. %, at least about 8 wt. %, or at least about 10 wt. %) and/or at most about 30 wt. % (e.g., at most about 25 wt. %, at most about 20 wt. %, or at most about 15 wt. %) of the solid weight of the dielectric film forming compositions described herein.

In some embodiments, the dielectric film forming compositions described herein can optionally further include at least one (e.g., two, three, or four) adhesion promoter.

Suitable adhesion promoters are described in “Silane Coupling Agent Edwin P. Plueddemann, 1982 Plenum Press, New York. Examples of such adhesion promoters are disclosed in, e.g., U.S. Pat. Nos. 10,036,952 and 10,563,014, and U.S. Application Publication No. 2015/0219990, and EP Patent No. 3,492,982; the entire contents of which are hereby incorporated by reference.

In some embodiments, the amount of the optional adhesion promoter is at least about 0.5 wt. % (e.g., at least about 0.8 wt. %, at least about 1 wt. %, or at least about 1.5 wt. %) and/or at most about 4 wt. % (e.g., at most about 3.5 wt. %, at most about 3 wt. %, at most about 2.5 wt. %, or at most about 2 wt. %) of the solid weight of the dielectric film forming compositions described herein.

In some embodiments, the dielectric film forming compositions described herein can optionally contain at least one (e.g., two, three, or four) surfactant. Examples of suitable surfactants include, but are not limited to, the surfactants described in JP-A-62-36663, JP-A-61-226746, JP-A-61-226745, JP-A-62-170950, JP-A-63-34540, JP-A-7-230165, JP-A-8-62834, JP-A-9-54432 and JP-A-9-5988, the entire contents of which are hereby incorporated by reference.

In some embodiments, the amount of the surfactant is at least about 0.005 wt. % (e.g., at least about 0.01 wt. % or at least about 0.1 wt. %) and/or at most about 1 wt. % (e.g., at most about 0.5 wt. % or at most about 0.2 wt. %) of the solid weight of the dielectric film forming compositions described herein.

In some embodiments, the dielectric film forming compositions described herein can optionally contain at least one (e.g., two, three, or four) corrosion inhibitor.

Examples of suitable corrosion inhibitors include triazole compounds, imidazole compounds and tetrazole compounds. Triazole compounds can include triazoles, benzotriazoles, substituted triazoles, and substituted benzotriazoles. The dielectric film forming compositions comprising corrosion inhibitors prevent corrosion and discoloration of copper or copper alloy when the photosensitive layer used on top of the copper or copper alloy. The corrosion inhibitor additive play a significant role in improving HAST stability of TEG chip by effectively binding in copper.

Examples of tetrazoles include 1-H-tetrazole, 5-methyl-1H-tetrazole, 5-phenyl-1H-tetrazole, 5-(ethylthio)-1H-tetrazole, 5-(benzylthio)-1H-tetrazole, ethyl 1H-tetrazole-5-acetate, ethyl 1H-tetrazole-5-carboxylate, 5-amino-1H-tetrazole, 1-phenyl-5-mercapto-1H-tetrazole, 5,5′-bis-1H-tetrazole, 1-methyl-5-ethyltetrazole, 1-methyl-5-mercaptotetrazole, 1-carboxymethyl-5-mercaptotetrazole, 5-amino-1H-tetrazole, 1-methyl-1H-tetrazole and the like.

Examples of triazole compounds of include, but are not limited to, 1,2,4-triazole, 1,2,3-triazole, or triazoles substituted with substituents such as C₁-C₈ alkyl (e.g., 5-methyltriazole), amino, thiol, mercapto, imino, carboxy and nitro groups.

Specific examples of triazole include 1,2,4-triazole, 1,2,3-triazole, 5-methyl-1,2,4-triazole, 3-amino-5-mercapto-1,2,4-triazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, and the like.

Examples of benzotriazole of include 1-H benzotriazole, tolyltriazole, 5-phenyl-benzotriazole, 5-nitro-benzotriazole, hydroxybenzotriazole, 2-(5-amino-pentyl)-benzotriazole, 5-phenylthiol-benzotriazole, 5-methyl-1H-benzotriazole, 4-methyl-1H-benzotriazole, 4-carboxy-1H-benzotriazole, 5-carboxy-1H-benzotriazole, 2-hydroxy-5-acrylyloxyphenyl-2H-benzotriazoles, 2-(5-methyl-2-hydroxyphenyl) benzotriazole, 2-(3-t-butyl-phenyl) 5-methyl-2-hydroxy-benzotriazole, 2-(3,5-di-t-amyl-2-hydroxyphenyl) benzotriazole, 2-hydroxy-3-chloro-5-acrylyloxyphenyl-2H-benzotriazoles and the like.

Examples of imidazole include, but are not limited to, 2-alkyl-4-methyl imidazole, 2-phenyl-4-alkyl imidazole, 2-methyl-4(5)-nitroimidazole, 5-methyl-4-nitroimidazole, 4-Imidazolemethanol hydrochloride, and 2-mercapto-1-methylimidazole.

The amount of the optional corrosion inhibitor, if employed, is at least about 0.1 wt. % (e.g., at least about 0.2 wt. % or at least about 0.5 wt. %) and/or at most about 3.0 wt. % (e.g., at most about 2.0 wt. % or at most about 1.0 wt. %) of the solid weight of the dielectric film forming compositions described herein. If the amount of corrosion inhibitor is more than the range, the storage stability is reduced, if the amount of corrosion inhibitor s less than the above range, voids between the copper or copper alloy surface is likely to occur.

In some embodiments, the dielectric film-forming compositions described herein include other optional components, such as one or more (e.g., two, three, or four) dyes, pigments, plasticizers, or antioxidants. Examples of such components have been described, e.g., in U.S. Application Publication No. 2022/0127459, the entire contents of which are hereby incorporated by reference.

In some embodiments, the positive formulation of the disclosure include a plasticizer, wherein the amount of the plasticizer present in the composition is an amount effective to reduce the sidewall angle of imaged and cured features in the coated film on the substrate to prevent stress failures in subsequent metallization of the substrate due to steep angles of the imaged features.

For some applications, microelectronic manufacturers and technologists request coating compositions that provide shallower or softer side wall geometries. If the sidewalls of the features that result from the photoimaging process are too vertical and/or form too sharp of an angle with the top surface of the coating, subsequent metallization of the features can lead to metal layers with high induced stress. Cracks and delamination of the metal layer may form in the regions of high stress. These cracks can propagate through the metal layer structure to such an extent that device functional failure results due to an open circuit. In addition, bond pads that have a coating with vertical side walls may be difficult to wire bond since the bonding head may not fit between the vertical walls. Clearly, a tapered sidewall with rounded edges is needed. The present invention discloses new photosensitive compositions containing poly-o-hydroxyamide precursor polymers and a plasticizer that has a low vapor pressure at the typical soft bake temperatures (100-150 degrees centigrade) of the film. The presence of these plasticizers in the formulation helps to provide shallower wall angles, or rounder corners and edges. For the purpose of this invention then, a plasticizer is defined as a compound when present in the compositions of this invention is capable of producing such shallower wall angles and/or rounder corners and edges during the curing cycle of the poly-o-hydroxyamide precursor in features photoimaged from coatings cast from the compositions of this invention.

In one embodiment of the present invention concerning the diazoquinone containing positive working photosensitive poly-o-hydroxyamide precursor composition the plasticizer is at least one polyhydroxy compound with at least two OH groups and whose boiling point is higher than the boiling point of the diazoquinone containing positive working photosensitive poly-o-hydroxyamide precursor composition solvent. Examples of polyhydroxy compounds with at least two OH groups include, but are not limited to, ethylene glycol, diethylene glycol, polyethylene glycol, propylene glycol, tripropylene glycol, polypropylene glycol, glycerol, butane diol, hexane diol, sorbitol, cyclohexanediol, 4,8-bis(hydroxymethyl)-tricyclo(5.2.1.0/2,6)decane and a 2-oxepanone co-polymer with 2-ethyl-2-(hydroxymethyl)-1,3-propanediol. Preferred polyhydroxy compounds with at least two OH groups are diethylene glycol, tripropylene glycol, and a 2-oxepanone co-polymer with 2-ethyl-2-(hydroxymethyl)-1,3-propanediol. More preferred polyhydroxy compounds with at least two OH groups are tripropylene glycol and a 2-oxepanone co-polymer with 2-ethyl-2-(hydroxymethyl)-1,3-propanediol.

The amount of plasticizer used in the diazoquinone containing positive working photosensitive poly-o-hydroxyamide precursor composition of this invention is from about 0.1 weight percent to about 20 weight percent of the total weight of the composition, preferably, from about 1 weight percent to about 10 weight percent, more preferably, from about 1.25 weight percent to about 7.5 weight percent and most preferably, from about 1.5 weight percent to about 5 weight percent. The plasticizers may be blended in any suitable ratio.

In some embodiments, the positive formulation of the disclosure includes a silane diol such as diarylsilane diol or dialkylsilane diol as additive as dissolution inhibitor. Most preferred is a diphenylsilane diol. The silane diol is included in the composition at about 0.1 weight percent to 10.0 weight percent, preferably at about 0.5 weight percent to 7.5 weight percent, and most preferably at about 1 weight percent to 5 weight percent.

In some embodiments, the dielectric film-forming compositions described herein are substantially fluorine-free compositions wherein poly-o-hydroxyamide photosensitive diazoquinone compounds, sensitizers, adhesion promoters, surfactants, solvents, corrosion inhibitors, plasticizers and additives are all substantially fluorine free. In another embodiments, the dielectric film-forming compositions described herein are free of per- and polyfluoroalkyl substances (PFAS), wherein poly-o-hydroxyamide, photoacid generators, basic compounds, photobase generators, sensitizers, adhesion promoters, surfactants, solvents, corrosion inhibitors, plasticizers and additives are free of per- and polyfluoroalkyl substances (PFAS). In some embodiments, the dielectric film-forming compositions described herein are substantially halogen free wherein poly-o-hydroxyamide, photoacid generators, basic compounds, photobase generators, sensitizers, adhesion promoters, surfactants, solvents, corrosion inhibitors, plasticizers and additives are substantially halogen free.

In other embodiments, the disclosure provides methods of use for compositions of the disclosure and articles of manufacture, particularly electronic parts, obtained by the combination of the composition and the method of use according to the disclosure. The methods of the disclosure include methods for forming a patterned image on a substrate. The method comprises the steps of:
(a) providing a substrate,
(b) coating on said substrate a negative photosensitive composition comprising one or more poly-o-hydroxyamide precursors having the structure (2)
at least one solvent and at least one dissolution rate modifier (all as described above) with the proviso that when the latent crosslinker is highly reactive, the dissolution rate modifier does not contain carboxylic acid groups, thereby forming a coated substrate;
(c) exposing the coated substrate to actinic radiation;
(d) post exposure baking the coated substrate at an elevated temperature;
(e) developing the coated substrate with an aqueous developer, thereby forming a relief image; and
(f) baking the substrate at an elevated temperature, thereby curing the relief image and forming a heat resistant film.

In some embodiments, a dielectric film can be prepared from a dielectric film forming composition described herein by a method including the steps of: (a) coating the dielectric film forming composition described herein on a substrate (e.g. a semiconductor substrate) to form a dielectric film; and (b) optionally baking the film at an elevated temperature (e.g., from about 50° C. to about 150° C.) for a period of time (e.g., from about 20 seconds to about 600 seconds).

Coating methods for preparation of the dielectric film include, but are not limited to, (1) spin coating, (2) spray coating, (3) roll coating, (4) rod coating, (5) rotation coating, (6) slit coating, (7) compression coating, (8) curtain coating, (9) die coating, (10) wire bar coating, (11) knife coating and (12) lamination of dry film. In case of coating methods (1)-(11), the dielectric film forming composition is typically provided in the form of a solution. One skilled in the art would choose the appropriate solvent type and solvent concentration based on the coating type.

Substrates can have circular, square or rectangular shapes such as wafers or panels in various dimensions. Examples of suitable substrates are epoxy molded compound (EMC), silicon, glass, copper, stainless steel, copper cladded laminate (CCL), aluminum, silicon oxide and silicon nitride. Substrates can be flexible such as polyimide, PEEK, polycarbonate, and polyester films. Substrates can have surface mounted or embedded chips, dyes, or packages. Substrates can be sputtered or pre-coated with a combination of seed layer and passivation layer. In some embodiments, the substrates mentioned herein can be a semiconductor substrate. As used herein, a semiconductor substrate is a substrate (e.g., a silicon or copper substrate or wafer) that becomes a part of a final electronic device.

The thickness of the dielectric film of this disclosure is not particularly limited. In some embodiments, the dielectric film has a film thickness of at least about 1 micron (e.g., at least about 2 microns, at least about 3 microns, at least about 4 microns, at least about 5 microns, at least about 6 microns, at least about 8 microns, at least about 10 microns, at least about 15 microns, at least about 20 microns, or at least about 25 microns) and/or at most about 100 microns (e.g., at most about 90 microns, at most about 80 microns, at most about 70 microns at most about 60 microns, at most about 50 microns, at most about 40 microns, or at most about 30 microns). In some embodiments, the thickness of the dielectric film is less than about 5 microns (e.g., less than about 4.5 microns, less than about 4.0 microns, less than about 3.5 microns, less than about 3.0 microns, less than about 2.5 microns, or less than about 2.0 microns).

In some embodiments, when the dielectric film forming composition is photosensitive, the method to prepare a patterned photosensitive dielectric film includes converting the photosensitive dielectric film into a patterned dielectric film by a lithographic method. In such cases, the conversion can include exposing the photosensitive dielectric film to high energy radiation (such as electron beams, ultraviolet light, and X-ray) using a patterned mask.

After the exposure, the dielectric film can be heat treated from at least about 50° C. (e.g., at least about 55° C., at least about 60° C., or at least about 65° C.) to at most about 100° C. (e.g., at most about 95° C., or at most about 90° C., at most about 85° C., at most about 80° C., at most about 75° C., or at most about 70° C.) for at least about 60 seconds (e.g., at least about 65 seconds, or at least about 70 seconds) to at most about 240 seconds (e.g., at most about 180 seconds, at most about 120 seconds or at most about 90 seconds). The heat treatment is usually accomplished by use of a hot plate or oven.

After the exposure and heat treatment, the dielectric film can be developed to remove unexposed portions by using a developer to form openings or a relief image on the substrate. Development can be carried out by, for example, an immersion method or a spraying method. Microholes and fine lines can be generated in the dielectric film on the laminated substrate after development.

In some embodiments, the dielectric film can be developed by using an aqueous developer. When the developer is an aqueous solution, it preferably contains one or more aqueous bases. Examples of suitable bases include, but are not limited to, inorganic alkalis (e.g., potassium hydroxide, sodium hydroxide, sodium carbonate, potassium carbonate), primary amines (e.g., ethylamine, n-propylamine), secondary amines (e.g., diethylamine, di-n-propylamine), tertiary amines (e.g., triethylamine), alcoholamines (e.g., triethanolamine), quaternary ammonium hydroxides (e.g., tetramethylammonium hydroxide or tetraethylammonium hydroxide), and mixtures thereof. The concentration of the base employed will vary depending on, e.g., the base solubility of the polymer employed. The most preferred aqueous developers are those containing tetramethylammonium hydroxide (TMAH). Suitable concentrations of TMAH range from about 1% to about 5%.

In some embodiments, after the development step or the optional rinse treatment step, an optional baking step (e.g., post development bake) can be carried out at a temperature ranging from at least about 120° C. (e.g., at least about 130° C., at least about 140° C., at least about 150° C., at least about 160° C., at least about 170° C., or at least about 180° C.) to at most about 250° C. (e.g., at most about 240° C., at most about 230° C., at most about 220° C., at most about 210° C., at most about 200° C. or at most about 190° C.). The baking time is at least about 5 minutes (e.g., at least about 10 minutes, at least about 20 minutes, at least about 30 minutes, at least about 40 minutes, at least about 50 minutes, or at least about 60 minutes) and/or at most about 5 hours (e.g., at most about 4 hours, at most about 3 hours, at most about 2 hours, or at most about 1.5 hours). This baking step can remove residual solvent from the remaining dielectric film and can further crosslink the remaining dielectric film. Post development bake can be done in air or preferably, under a blanket of nitrogen and may be carried out by any suitable heating means.

The benzoxazole ring is then formed by curing of the uncured relief pattern to obtain the final high heat resistant pattern. Curing is performed by baking the developed, uncured relief pattern at or above the glass transition temperature (T_{g}) of the photosensitive composition to obtain the benzoxazole ring that provides high heat resistance. Typically, temperatures above about 200 C are used. In some embodiments, temperatures from about 250 degrees centigrade to about 400 degrees centigrade are applied. The curing time is from about 15 minutes to about 24 hours depending on the heating method employed. In some embodiments the curing time is from about 20 minutes to about 5 hours. In some embodiments the curing time is from about 30 minutes to about 3 hours. Curing can be done in air or under a blanket of nitrogen and may be carried by any suitable heating means, including baking on a hot plate or in a convection oven.

In some embodiments, the poly-o-hydroxyamide precursor is cured at temperatures sufficient to affect cyclodehydration, thereby forming a benzoxazole ring where A1 and A2 are substituted or unsubstituted alkyl or aromatic group.

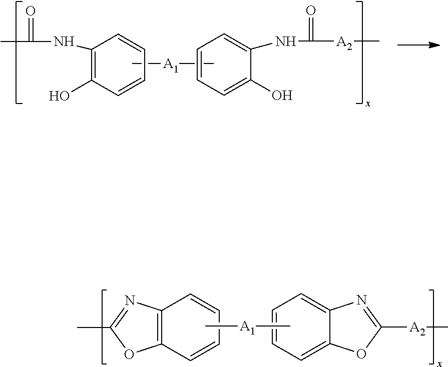

Curing of poly-O-hydroxyamide precursor 2 and 3 will transform to 2c and 3c.

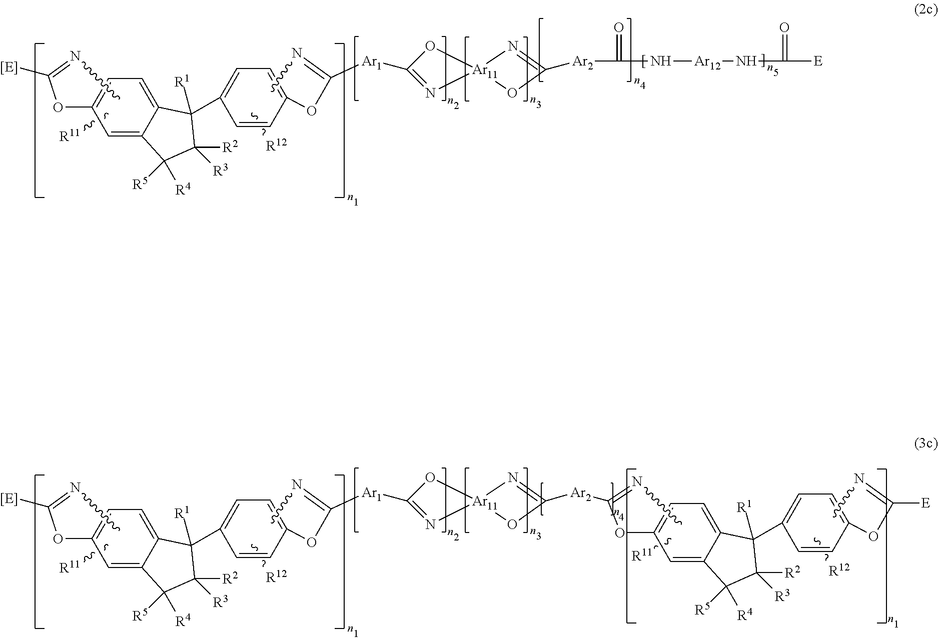

wherein R¹, R², R³, R⁴, R⁵, R¹¹, R¹², Ar₁, Ar₂, Ar₁₁, n¹, n², n³, n⁴ and E have the same meaning as described earlier.

In some embodiments, the patterned dielectric film includes at least one element having a feature size of at most about 10 microns (e.g., at most about 9 microns, at most about 8 microns, at most about 7 microns, at most about 6 microns, at most about 5 microns, at most about 4 microns, at most about 3 microns, at most about 2 microns, or at most about 1 micron). In certain embodiments of this disclosure the dielectric films prepared from the dielectric film forming composition described herein can produce a patterned film with a feature size of at most about 3 microns (e.g., at most 2 microns or at most 1 micron) by a laser ablation method.

In some embodiments, the embodiment ratio (ratio of height to width) of a feature (e.g., the smallest feature) of the patterned dielectric film of this disclosure is at least about 1/3 (e.g., at least about 1/2, at least about 1/1, at least about 2/1, at least about 3/1, at least about 4/1, or at least about 5/1).

In some embodiments (e.g., when the dielectric film forming composition is non-photosensitive), the method to prepare a patterned dielectric film include converting the dielectric film into the patterned dielectric film by a laser ablation technique. Direct laser ablation method with an excimer laser beam is generally a dry, one step material removal to form openings (or patterns) in the dielectric film. In some embodiments, the wavelength of the laser is 640 nm or less (e.g., 157 nm, 193 nm, 248 nm, 308 nm, 351 nm, 405 nm, 445 nm, 470 nm, 520 nm, 528 nm, 555 nm, or 640 nm). Examples of suitable laser ablation methods include, but are not limited to, the methods described in U.S. Pat. Nos. 7,598,167, 6,667,551, and 6,114,240, the contents of which are hereby incorporated by reference.

In embodiments when the dielectric film forming composition is non-photosensitive, the composition can be used to form the bottom layer in a bilayer photoresist. In such embodiments, the top layer of the bilayer photoresist can be a photosensitive layer and can be patterned upon exposure to high energy radiation. The pattern in the top layer can be transferred to the bottom dielectric layer (e.g., by etching). The top layer can then be removed (e.g., by using a wet chemical etching method) to form a patterned dielectric film.

In some embodiments, this disclosure features a method for depositing a metal layer (e.g., to create an embedded copper trace structure) that includes the steps of: (a) forming a patterned dielectric film having openings; and d) depositing a metal layer (e.g., an electrically conductive metal layer) in at least one opening in the patterned dielectric film. In some embodiments, the method can include the steps of: (a) depositing a dielectric film forming composition described herein on a substrate (e.g., a semiconductor substrate) to form a dielectric film; (b) exposing the dielectric film to a source of radiation or heat or a combination thereof (e.g., through a mask); (c) patterning the dielectric film to form a patterned dielectric film having openings; and (d) depositing a metal layer (e.g., an electrically conductive metal layer) in at least one opening in the patterned dielectric film. In some embodiments, steps (a)-(d) can be repeated one or more (e.g., two, three, or four) times.

In some embodiments, this disclosure features a method to deposit a metal layer (e.g., an electrically conductive copper layer to create an embedded copper trace structure) on a semiconductor substrate. In some embodiments, a seed layer conformal to the patterned dielectric film is first deposited on the patterned dielectric film (e.g., outside the openings in the film). Seed layers can contain a barrier layer and a metal seeding layer (e.g., a copper seeding layer). In some embodiments, the barrier layer is prepared by using materials capable of preventing diffusion of an electrically conductive metal (e.g., copper) through the dielectric layer. Suitable materials that can be used for the barrier layer include, but are not limited to, tantalum (Ta), titanium (Ti), tantalum nitride (TiN), tungsten nitride (WN), and Ta/TaN. A suitable method of forming the barrier layer is sputtering (e.g., PVD or physical vapor deposition). Sputtering deposition has some advantages as a metal deposition technique because it can be used to deposit many conductive materials, at high deposition rates, with good uniformity and low cost of ownership. Conventional sputtering fill produces relatively poor results for deeper, narrower (high-embodiment-ratio) features. The fill factor by sputtering deposition has been improved by collimating the sputtered flux. Typically, this is achieved by inserting between the target and substrate a collimator plate having an array of hexagonal cells.

Next step in the method is metal seeding deposition. A thin metal (e.g., an electrically conductive metal such as copper) seeding layer can be formed on top of the barrier layer in order to improve the deposition of the metal layer (e.g., a copper layer) formed in the succeeding step.

Next step in the method is depositing an electrically conductive metal layer (e.g., a copper layer) on top of the metal seeding layer in the openings of the patterned dielectric film wherein the metal layer is sufficiently thick to fill the openings in the patterned dielectric film. The metal layer to fill the openings in the patterned dielectric film can be deposited by plating (such as electroless or electrolytic plating), sputtering, plasma vapor deposition (PVD), and chemical vapor deposition (CVD). Electrochemical deposition is generally a preferred method to apply copper since it is more economical than other deposition methods and can flawlessly fill copper into the interconnect features. Copper deposition methods generally should meet the stringent requirements of the semiconductor industry. For example, copper deposits should be uniform and capable of flawlessly filling the small interconnect features of the device, for example, with openings of 100 nm or smaller. This technique has been described, e.g., in U.S. Pat. Nos. 5,891,804, 6,399,486, and 7,303,992, the contents of which are hereby incorporated by reference.

In some embodiments, the method of depositing an electrically conductive metal layer further includes removing overburden of the electrically conductive metal or removing the seed layer (e.g., the barrier layer and the metal seeding layer). In some embodiments, the overburden of the electrically conductive metal layer (e.g., a copper layer) is at most about 3 microns (e.g., at most about 2.8 microns, at most about 2.6 microns, at most about 2.4 microns, at most about 2.2 microns, at most about 2.0 microns, or at most about 1.8 microns) and at least about 0.4 micron (e.g., at least about 0.6 micron, at least about 0.8 micron, at least about 1.0 micron, at least about 1.2 micron, at least about 1.4 micron, or at least about 1.6 microns). Examples of copper etchants for removing copper overburden include an aqueous solution containing cupric chloride and hydrochloric acid or an aqueous mixture of ferric nitrate and hydrochloric acid. Examples of other suitable copper etchants include, but are not limited to, the copper etchants described in U.S. Pat. Nos. 4,784,785, 3,361,674, 3,816,306, 5,524,780, 5,650,249, 5,431,776, and 5,248,398, and US Application Publication No. 2017/0175274, the contents of which are hereby incorporated by reference.

Some embodiments describe a method for surrounding a metal structured substrate containing conducting metal (e.g., copper) wire structures forming a network of lines and interconnects with the dielectric film described herein. The method includes
a) providing a substrate containing conducting metal wire structures that form a network of lines and interconnects on the substrate.
b) depositing a dielectric film forming composition described herein on the substrate to form a dielectric film (e.g., that surrounds the conducting metal lines and interconnects); and
c) exposing the dielectric film to a source of radiation or heat or a combination of radiation and heat (with or without a mask).

The above steps can be repeated multiple times (e.g., two, three, or four times) to form a complex multi-layered three-dimensional object.

In some embodiments, this disclosure features a method of preparing a dry film structure. The method includes:
a) coating a carrier substrate (e.g., a substrate including at least one polymeric or plastic film) with a dielectric film forming composition described herein.
b) drying the coated dielectric film forming composition to form a dielectric layer (e.g., a photosensitive, dielectric layer); and
c) optionally, applying a protective layer to the dry film structure.

In some embodiments, the carrier substrate is a single or multiple layer polymeric or plastic film, which can include one or more polymers (e.g., polyethylene terephthalate). In some embodiments, the carrier substrate has excellent optical transparency, and it is substantially transparent to actinic irradiation used to form a relief pattern in the polymer layer. The thickness of the carrier substrate is preferably in the range of at least about 10 μm (e.g., at least about 15 μm, at least about 20 μm, at least about 30 μm, at least about 40 μm, at least about 50 μm, or at least about 60 μm) to at most about 150 μm (e.g., at most about 140 μm, at most about 120 μm, at most about 100 μm, at most about 90 μm, at most about 80 μm, or at most about 70 μm).

In some embodiments, the protective layer is a single or multiple layer film, which can include one or more polymers (e.g., polyethylene or polypropylene). Examples of carrier substrates and protective layers have been described in, e.g., U.S. Application Publication No. 2016/0313642, the contents of which are hereby incorporated by reference.

Reliability is the probability that an electronic component will perform the required function under stressed conditions for a designated period. Preconditioning, Temperature Humidity Bias (THB), Biased Humidity Stress Test (bHAST), Unbiased HAST (uHAST), High Temp Storage (HTS) are commonly used stress test applied for semiconductor packaging materials. Reliability is measured as the proportion of devices used from time zero that will not have failed by a given time ‘t’.

The Highly Accelerated Stress Test (HAST) combines high temperature, high humidity, high pressure, and time to measure component reliability with or without electrical bias. In a controlled environment, HAST testing accelerates the stresses of the more traditional tests. It essentially functions as a corrosion failure test. Corrosion type failures are accelerated, uncovering flaws such as in packaging seals, materials, and joints over a short period of time.

Biased Highly Accelerated Stress Tests (bHAST) utilize the same variables (high pressure, high temperature and time) as HAST Tests, but add a voltage bias. The goal of BHAST testing is to accelerate corrosion within the device, thereby speeding up the test period. In unbiased HAST tests, humidity accelerates failure mechanisms related the presence of moisture for non-hermetic packages. Biased voltage under high humidity causes galvanic and electrochemical corrosion in non-hermitic packages in biased Humidity Stress Test (bHAST). For advanced/emerging package technologies, board level reliability (BLR) testing is conducted to determine the solder joint interconnect reliability using daisy-chained test vehicles. Failure analysis is conducted on failed samples to determine the cause.

As an accelerated version of the traditional non-condensing THB (temperature humidity bias) test, the HAST test has the advantage of adding high pressure and higher temperatures (up to 149° C.) to accelerate temperature and moisture induced failures in roughly one-tenth the time of THB. HAST and BHAST testing is usually run at 130° C./85% RH, but the conditions can also vary.

Typical HAST test conditions consist of 110 or 130° C. temperature, and 85% RH humidity and a test run time of 96 hours or 200 hours. Once the highly accelerated stress test is completed, tested samples are analyzed by microscope and SEM for changes happen during HAST conditions. HAST testing generally follows JEDEC spec JESD22 A110, “Highly Accelerated Temperature and Humidity Stress Test (HAST).” Biased Humidity Stress Test (bHAST) is the most sensitive stress test for reliability of a microelectronic device by using an organic dielectric film composition. Examples of bHAST methods used in evaluation of semiconductor devices have been described in, e.g., U.S. Pat. No. 9,874,813 and US patent application 2021/0272898 and the contents of which are hereby incorporated by reference.

TEG (Test Element Group) wafer with Cu post (pillar) plating was used for evaluation of wafer for such as material development, package stability under HAST conditions by inspection method. Examples of TEG wafers used in evaluation of semiconductor devices have been described in, e.g., U.S. Pat. Nos. 8,237,450 and 9,082,708, the contents of which are hereby incorporated by reference.

In some embodiments, the dielectric film of the dry film structure can be delaminated from carrier layer as a self-standing dielectric film. A self-standing dielectric film is a film that can maintain its physical integrity without using any support layer such as a carrier layer. In some embodiments, the self-standing dielectric film is not crosslinked or cured and can include the components of the dielectric film forming composition described above except for the solvent.

In some embodiments, the dielectric loss tangent or dissipation factor of the dielectric film prepared from dielectric film forming composition described herein measured at 10 GHz, 15 GHz, and/or 35 GHz is in the range of from at least about 0.001 (e.g., at least about 0.002, at least about 0.003, at least about 0.004, at least about 0.005, at least about 0.01, or at least about 0.05) to at most about 0.1 (e.g., at most about 0.08, at most about 0.06, at most about 0.05, at most about 0.04, at most about 0.02, at most about 0.01, at most about 0.008, at most about 0.006, or at most about 0.005).

In some embodiments, the dielectric film of the dry film structure can be laminated to a substrate (e.g., a semiconductor substrate such as a wafer) using a vacuum laminator at about 50° C. to about 140° C. after pre-laminating of the dielectric film of the dry film structure with a plane compression method or a hot roll compression method. When the hot roll lamination is employed, the dry film structure can be placed into a hot roll laminator, the optional protective layer can be peeled away from the dielectric film/carrier substrate, and the dielectric film can be brought into contact with and laminated to a substrate using rollers with heat and pressure to form an article containing the substrate, the dielectric film, and the carrier substrate. The dielectric film can then be exposed to a source of radiation or heat (e.g., through the carrier substrate) to form a crosslinked dielectric film. In some embodiments, the carrier substrate can be removed before exposing the dielectric film to a source of radiation or heat.

Some embodiments of this disclosure describe a method of generating a planarizing dielectric film on a substrate with copper pattern. In some embodiments, the method includes depositing a dielectric film forming composition onto a substrate with copper pattern to form a dielectric film. In some embodiments, the method includes steps of:
a. providing a dielectric film forming composition of this disclosure, and
b. depositing the dielectric film forming composition onto a substrate with a copper pattern to form a dielectric film, wherein the difference in the highest and lowest points on a surface of the dielectric film is at most about 2 microns (e.g., at most about 1.5 microns, at most about 1 micron, or at most about 0.5 micron).

In some embodiments, this disclosure features an article (or a three-dimensional object) containing at least one patterned dielectric film formed by a method described herein. Examples of such articles include a semiconductor substrate, a flexible film for electronics, a wire isolation, a wire coating, a wire enamel, and an inked substrate. In some embodiments, this disclosure features semiconductor devices that include one or more of these articles. Examples of semiconductor devices that can be made from such articles include an integrated circuit, a light emitting diode, a solar cell, and a transistor.

The present disclosure is illustrated in more detail with reference to the following examples, which are for illustrative purposes and should not be construed as limiting the scope of the present disclosure.

### EXAMPLES

### Synthesis Example 1: Synthesis of poly-o-hydroxyamide Precursor

To a 250 mL three-necked round bottom jacketed flask equipped with a mechanical stirrer, nitrogen inlet and an addition funnel, 13.23 g indane bis-o-aminophenol [6-amino-3-(3′-amino-4′-hydroxyphenyl)-1,1,3-trimethyl-2,3-dihydro-1H-inden-5-ol], 13.71 g of pyridine and 70 g of NMP (N-methyl pyrrolidone) were added. The solution was stirred at room temperature until it is clear and then cooled at −5 to −9° C. To this solution, 3.85 g isophthalyl chloride (IC) and 5.60 g of 4,4′-oxydibenzoyl chloride dissolved in 21 g of NMP was added dropwise. After the addition, the resulting mixture was stirred at room temperature for 18 hours. Then, 1.06 g of pyridine and 2.20 g of nadic anhydride were added to the flask and the temperature was raised to 90° C. and stirred for 12 h. After cooling to room temperature, the viscous solution was precipitated in 1000 mL of de-ionized water. The polymer was collected by filtration and washed with deionized water and then with a 50/50 water/methanol mixture. The polymer was dried under vacuum at 60° C. for 24 hours to give a poly-o-hydroxyamides precursor. Weight average molecular weight (Mw) was 13,200 measured by GPC.

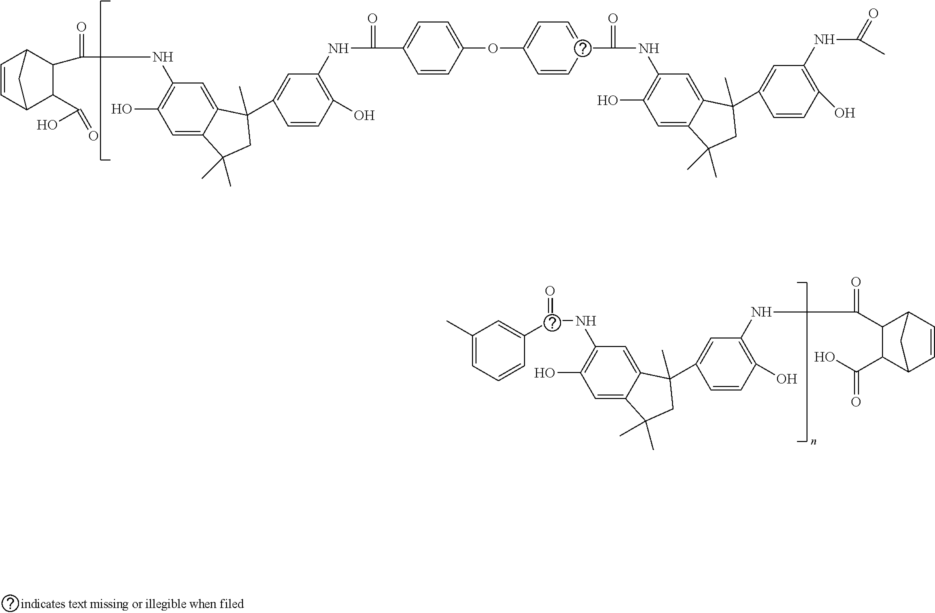

### Synthesis Example 2: Synthesis of poly-o-hydroxyamide Precursor

To a 1000 mL three-necked round bottom jacketed flask equipped with a mechanical stirrer, nitrogen inlet and an addition funnel, 66.21 g indane bis-o-aminophenol, 34.3 g of pyridine and 266 g of NMP were added. The solution was stirred at room temperature until it was clear and then cooled at −5 to −9° C. To this solution, 18.14 g isophthalyl chloride, 26.37 g of 4,4′-oxydibenzoyl chloride and 2.67 g of sebacoyl chloride dissolved in 188 g of NMP were added drop-wise. After the addition, the resulting mixture was stirred at room temperature for 18 hours. The viscous solution was precipitated in 3000 mL of de-ionized water. The polymer was collected by filtration and washed with deionized water and then with a 50/50 water/methanol mixture. The polymer was dried under vacuum at 60° C. for 24 hours to give a poly-o-hydroxyamides precursor.

### Synthesis Example 3: Synthesis of poly-o-hydroxyamide Precursor

To a 1000 mL three-necked round bottom jacketed flask equipped with a mechanical stirrer, nitrogen inlet and an addition funnel, 62.93 g indane bis-o-aminophenol, 4.56 g 2,2-Bis [4-(4-aminophenoxy)phenyl]propane (BAPP), 17.5 g of pyridine and 255 g of NMP are added. The solution is stirred at room temperature until it is clear and then cooled at −5 to −9° C. To this solution, 18.03 g isophthalyl chloride and 26.4 g of 4,4′-oxydibenzoyl chloride and 2.03 g of adipoyl chloride dissolved in 200 g of NMP is added drop-wise. After the addition, the resulting mixture is stirred at room temperature for 18 hours. The viscous solution is precipitated in 3000 mL of de-ionized water. The polymer is collected by filtration and washed with deionized water and then with a 50/50 water/methanol mixture. The polymer is dried under vacuum at 60° C. for 24 hours to give a poly-o-hydroxyamides precursor.

### Synthesis Example 4: Synthesis of poly-o-hydroxyamide Precursor with DNQ Cap

To a 100 mL three-necked round bottom flask equipped with a mechanical stirrer, 5.0 g (17.5 mmol) of the polymer obtained in Synthesis Example 1 and 50 mL of tetrahydrofuran (THF) are added. The mixture is stirred for ten minutes and the solid is fully dissolved. 0.92 g (3.5 mmole) of example 1, 1-naphthoquinonediazide-5-sulfonyl chloride is then added and the mixture is stirred for another 10 minutes. Triethylamine, 0.36 g (3.5 mmol), is added gradually within 15 minutes and then the reaction mixture is stirred for 5 hours. The reaction mixture is then added gradually to 500 mL of vigorously stirred de-ionized water. The precipitated product is separated by filtration and washed with 200 mL of de-ionized water. To the product is added another 600 mL de-ionized water and the mixture vigorously stirred for 30 minutes. After filtration the product is washed with 100 mL de-ionized water. The isolated product is dried at 40° C. overnight. The yield is 90%.

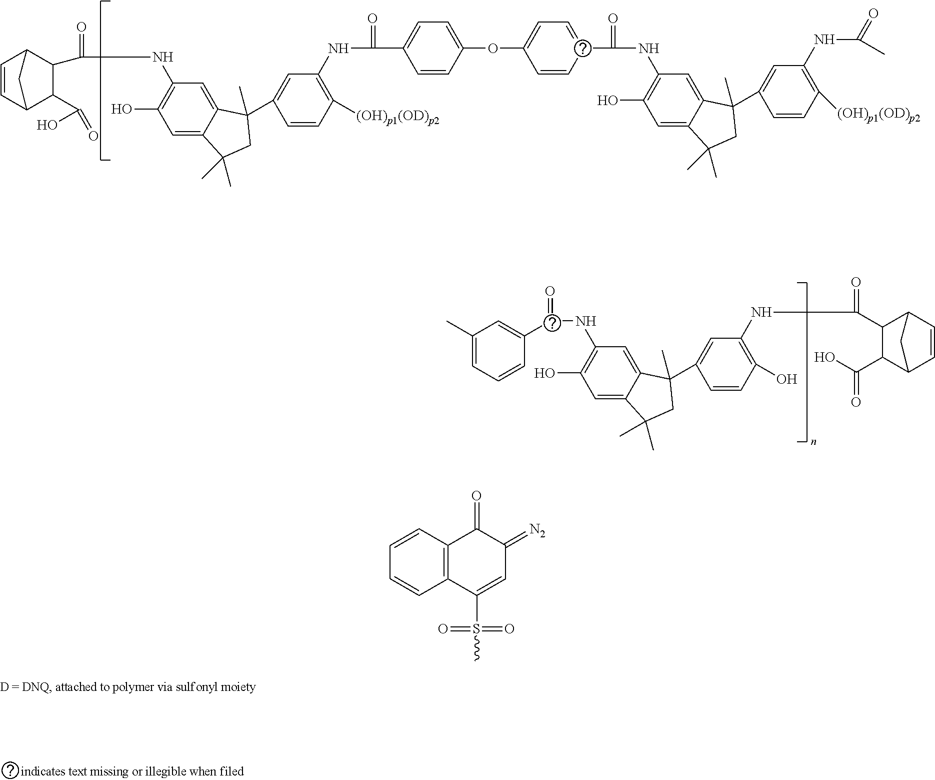

### Synthesis Example 5: Synthesis of poly-o-hydroxyamide Precursor

To a 250 mL three-necked round bottom jacketed flask equipped with a mechanical stirrer, nitrogen inlet and an addition funnel, 13.23 g Indane bis-o-aminophenol, 13.71 g of pyridine and 70 g of NMP were added. The solution was stirred at room temperature until it is clear and then cooled at −5 to −9° C. To this solution, 3.94 g isophthalyl chloride (IC) and 5.73 g of 4,4′-Oxydibenzoyl chloride dissolved in 21 g of NMP was added dropwise. After the addition, the resulting mixture was stirred at room temperature for 18 hours. Then, 1.06 g of pyridine and 2.20 g of nadic anhydride were added to the flask and the temperature was raised to 90° C. and stirred for 12 h. After cooling to room temperature, the viscous solution was precipitated in 1000 mL of de-ionized water. The polymer was collected by filtration and washed with deionized water and then with a 50/50 water/methanol mixture. The polymer was dried under vacuum at 60° C. for 24 hours to give a poly-o-hydroxyamides precursor. Weight average molecular weight (Mw) was 14,500 measured by GPC.

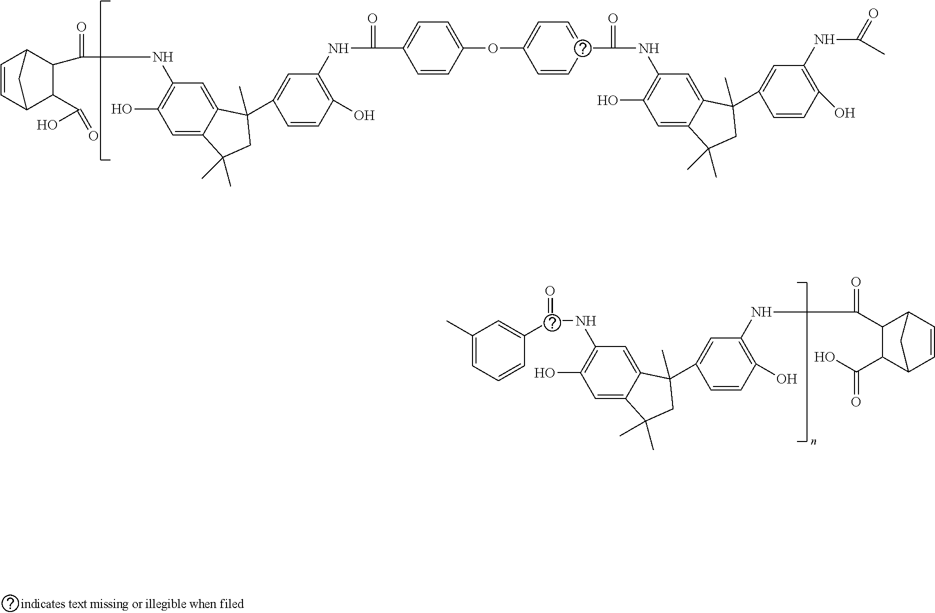

### Photosensitive Composition Example 1

A positive acting photosensitive composition is prepared by mixing 100 parts by weight of a polymer solid prepared by the method described in Synthesis Example 1, 3 parts by weight of gamma-ureidopropyltrimethoxysilane (Silquest A 1524 available from Momentive Performance Materials Inc), 2.5 parts by weights diphenylsilane diol, 13.5 parts by weight Mixed ester PAC (Bisphenol AP PAC) and 230.5 parts by weight GBL and is filtered through a 0.2 micro m Teflon filter.

### Photosensitive Composition Example 2

A positive acting photosensitive composition is prepared by mixing 100 parts by weight of a polymer solid prepared by the method described in Synthesis Example 1, 3 parts by weight of gamma-ureidopropyltrimethoxysilane (Silquest A 1524 available from Momentive Performance Materials Inc), 2.5 parts by weights diphenylsilane diol, 13.5 parts by weight Mixed ester PAC (Bisphenol AP PAC) and 230.5 parts by weight GBL and is filtered through a 0.2 micro m Teflon filter.

A silicon wafer is then coated with the above photosensitive composition and hotplate baked for 3 minutes at 125 degrees centigrade, resulting in a film thickness of 9 micro m. The film is exposed utilizing an i-line stepper with a patterned exposure array. Segments of the film on the wafer are exposed at various levels of exposure energy using a Canon 4000 IE i-line stepper. The wafer is post exposure baked at 130 degrees centigrade for 90 seconds. The wafer is developed with 2.38 percent aqueous TMAH solution using two 30 second puddle development steps with spin steps to remove spent developer in between applications of developer. The developed film is rinsed with deionized water and dried by spinning for 10 seconds at 5000 rpm to provide a relief pattern. No unexposed film thickness loss is observed. 2 micro m and 8 micro m features are resolved at exposure energies of 200 mJ/cm² and 175 mJ/cm² respectively.

### Photosensitive Composition Example 3

A positive acting photosensitive composition was prepared by mixing 100 parts by weight of a polymer solid prepared by the method described in Synthesis Example 1, 17 parts by weight P17 PAC, 2.4 parts Surfynol 440 in CPO 0.5% by weight (available from Evonik) and 270.6 parts by weight GBL and was filtered through a 5.0 micro m Teflon filter.

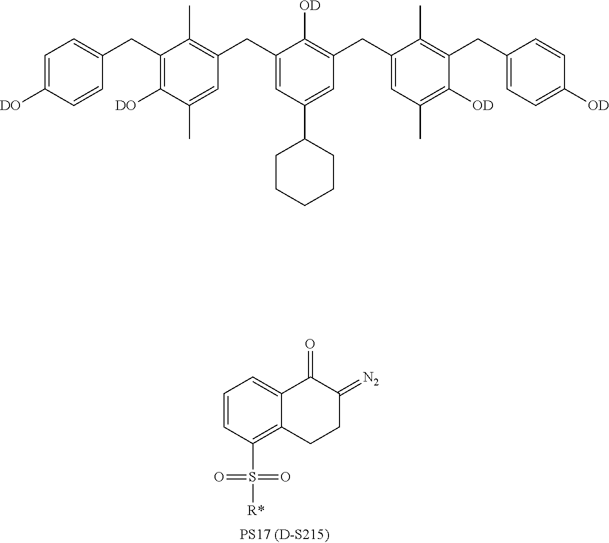

A silicon wafer was then coated with Photosensitive Composition (Photosensitive Composition Example 3) and baked on the hotplate for 2 minutes at 90 degrees centigrade, resulting in a film thickness of 9 micron. The film was exposed utilizing an i-line stepper with a patterned exposure array. Segments of the film on the wafer were exposed at various levels of exposure energy using a Canon 4000 IE i-line stepper. The wafer was developed with 2.38 percent aqueous TMAH solution (OPD 4262) using two 20 second puddle development steps with spin steps to remove spent developer in between applications of developer. The developed film was rinsed with deionized water and dried by spinning for 20 seconds at 5000 rpm to provide a relief pattern. No unexposed film thickness loss was observed. 3 micron patterns were resolved at exposure energies of 1350 mJ/cm².

### Adhesion Tests

The coated wafers are baked at 120 degrees centigrade for 3 minutes. The thickness of the films thus obtained is 7-8 mum. The wafers are then exposed pattern-wise using a broadband mercury lamp light for 108.2 seconds (the lamp output is 1000 mJ/cm² at 400 nm during the exposure time) with Karl Suss MA-56 broadband exposure tool. A ten-by-ten grid of 2 mm squares is thus created. Then, the wafer is baked at 120 degrees centigrade for 2 minutes and developed in 0.262 N aqueous tetramethylammonium hydroxide using puddle development (2 puddles, 25 sec each). The patterned films is cured under N₂ atmosphere at 350 degrees centigrade for 1 hour. The wafers are then placed in a pressure cooker pot and are exposed to saturated steam at 121 degrees centigrade for 100 hrs. Then, the adhesion of the films to the wafers is tested using a tape peel test using 3M tape #720 as described in ASTM D-3359-83. No squares of the grid are peeled off, and the formulation passes the test. Both films have no adhesion losses after 1000 hours of testing.

While the invention has been described in detail with reference to certain embodiments thereof, it will be understood that modifications and variations are within the spirit and scope of that which is described and claimed.

What is claimed is:

1. A polymer comprising a poly-o-hydroxyamide represented by the following structure: 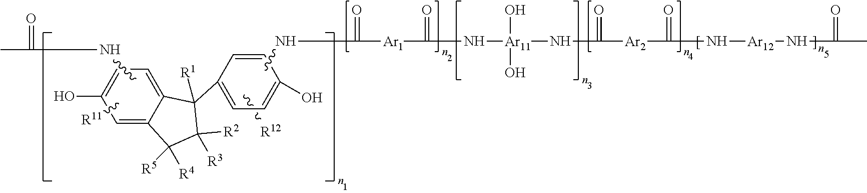
wherein each of R¹, R², R³, R⁴, and R⁵ independently, is a hydrogen atom, a substituted or unsubstituted C₁-C₁₂alkyl, a partially halogen substituted or fully halogen substituted C₁-C₁₂alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is independently a hydrogen atom, a linear or branched C₁-C₄ alkyl, a partially halogen substituted or fully halogen substituted C₁-C₄alkyl, a C₅-C₁₂ cycloalkyl, a C₆-C₁₈ aryl, a C₅-C₁₈ heteroaryl group, a C₁-C₄ alkoxy group or a halogen atom; Ar₁ and Ar₂ are each independently a divalent aromatic, aliphatic, or heterocyclic group, or mixtures thereof; Ar₁₁ and A₁₂ are a divalent aromatic, aliphatic, or heterocyclic group or a siloxane group; E is an end-capping group; n₁ is an integer from 5 to 200; n₃ is an integer from 0 to 200; n₅ is an integer from 0 to 200; n₂ is an integer from 5 to 200 and n₄ is an integer from 0 to 200;

2. The polymer according to claim 1, having the structure 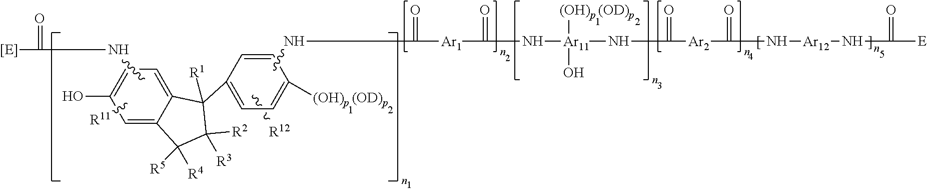
wherein D is selected from the group consisting of one of the following moieties: 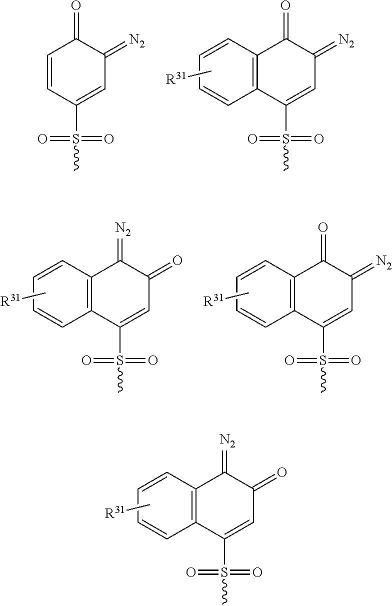
and R³¹ is selected from a group consisting of hydrogen atom, halogen, a C₁-C₄ alkyl group, a C₁-C₄ alkoxy group, a substituted or unsubstituted C₄-C₁₈ cycloalkyl; p₂ is any positive value of up to about 0.5, p₁ is any value from about 0.5 to about 1 with the proviso that (p₁+p₂)=1.3.

3. A positive photosensitive composition comprising:
(a) the polymer according to claim 1,
(b) a photoactive compound, and
(c) a solvent.

4. The composition of claim 3, wherein the at least one polymer is in an amount of from about 0.1% to about 55% by weight based on the solid weight of the composition.

5. A positive photosensitive composition according to claim 3, wherein the photoactive compound is a diazoquinone compound which generates an acid when exposed to light thereby increasing a dissolution rate of the polymer in an aqueous alkaline solution, relative to a dissolution rate of a polymer not exposed to light.

6. A positive photosensitive composition according to claim 3, further comprising at least one polyhydroxy compound with at least two OH groups as plasticizer and whose boiling point is higher than the boiling point of the diazoquinone containing positive working photosensitive poly-o-hydroxyamide precursor composition solvent.

7. A positive photosensitive composition according to claim 3, further comprising at least one adhesion promoter.

8. A positive photosensitive composition according to claim 3, further comprising at least amino or phenolic crosslinking agent which behave as latent crosslinkers generating intermediates in the presence of heat, or in the presence of thermogenerated or photogenerated acids.

9. The positive photosensitive composition of claim 3, further comprising: at least one member selected from the group consisting of a corrosion inhibitor, a sensitizer, a surfactant, a filler, a pigment, a dye.

10. A process for forming a relief pattern on a substrate, the process comprising the steps of:
(a) coating on a suitable substrate a positive photosensitive composition of claim 3, thereby forming a coated substrate,
(b) prebaking the coated substrate
(c) exposing the prebaked coated substrate to actinic radiation,
(d) developing the exposed coated substrate with an aqueous developer, thereby forming an uncured relief image on the coated substrate; and
(e) baking the developed coated substrate at an elevated temperature, thereby curing the relief image.

11. An article formed by the process of claim 10, wherein the article is a semiconductor device, a flexible film for electronics, a wire isolation, a wire coating, a wire enamel, or an inked substrate.

12. The article of claim 11, wherein the semiconductor device is an integrated circuit, a light emitting diode, a solar cell, or a transistor.

13. The polymer according to claim 1, wherein Ar₁ and Ar₂ each independently comprise a member selected from the group consisting of: 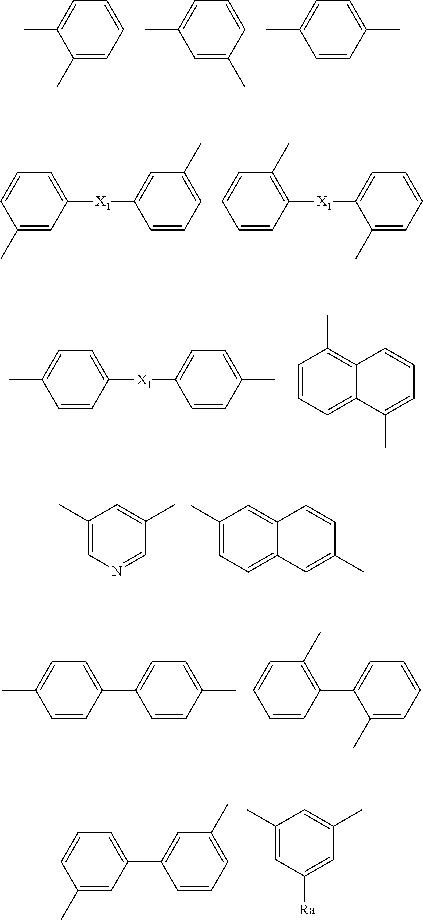
in which X₁ is —C(O)—C(O)—, —C(O)O—, -, a C₅-C₇ cyclic aliphatic group, fluorenyl group, —O—X₃—O, —O—C(O)—X₃—C(O)—O—, —C(O)—O—X₃—O—C(O)— or —(CH₂)ₘ—Si(Z)₂—O—Si(Z)₂—(CH₂)ₘ— where X₃ is a unsubstituted or substituted phenyl, diphenyl sulfone, isopropylidene diphenyl, hexafluoroisopropylidene diphenyl and Z is a H or a C₁-C₆ alkyl group and m is an integer from 1 to 6, Ra is each independently a hydrogen atom, an alkoxy, a fluoroalkoxy, a cycloalkyl, a cycloalkoxy, a cycloalkylsulfonyl, an aryloxy, an alkylaryloxy, an arylsulfonyl, or an alkylarylsulfonyl group.

14. The polymer according to claim 1, wherein Ar₁₁ comprises a member selected from the group consisting of: 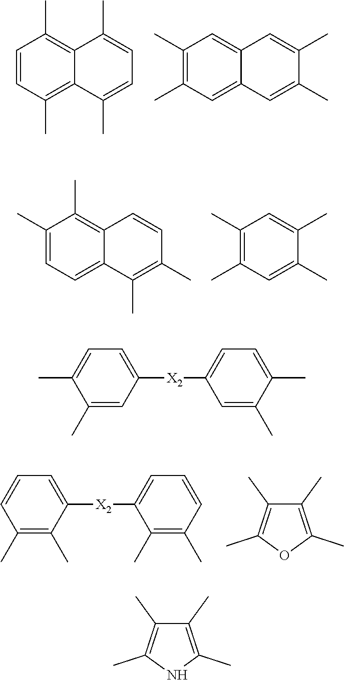
in which X₂ is —O—, —S—, —C(CF₃)₂—, —C(CH₃)₂—, —CH₂—, —SO₂—, —NHCO—, —C(O)—, —C(O)—C(O)—, —C(O)O—, a C₅-C₇ cyclic aliphatic group, fluorenyl group, —O—X₄—O, —O—C(O)—X₄—C(O)—O—, —C(O)—O—X₄—O—C(O)— or —(CH₂)ₘ—Si(Z)₂—O—Si(Z)₂—(CH₂)ₘ—, X₄ is a unsubstituted or substituted phenyl, diphenyl sulfone, isopropylidene diphenyl, hexafluoroisopropylidene diphenyl and Z and m have the same meaning as described above.

15. A process for providing an organic solution containing a poly-o-hydroxyamide polymer according to claim 1 in at least one polar, aprotic polymerization solvent; (b) adding at least one purification solvent to the organic solution to form a diluted organic solution, the at least one purification solvent is less polar than the at least one polymerization solvent and has a lower water solubility than the at least one polymerization solvent at 25° C.; (c) washing the diluted organic solution with acidified aqueous solution to obtain a washed organic solution; (d) removing at least a portion of the at least one purification solvent in the washed organic solution to obtain a solution containing a purified poly-o-hydroxyamide wherein the process avoids precipitation of the poly-o-hydroxyamide.

16. A polybenzoxazole obtained by curing a poly-o-hydroxyamide of claim 1, wherein the polybenzoxazole has the structure: 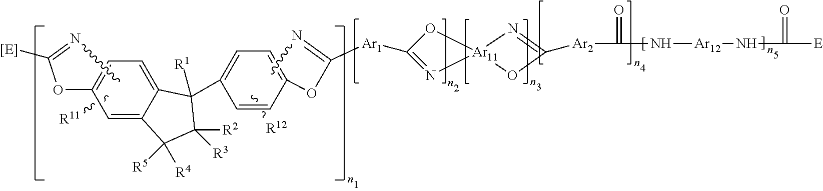
wherein each of R¹, R², R³, R⁴, and R⁵ independently, is a hydrogen atom, a substituted or unsubstituted C₁-C₁₂ alkyl, a partially halogen substituted or fully halogen substituted C₁-C₁₂ alkyl, a substituted or unsubstituted C₄-C₁₈ cycloalkyl, a substituted or unsubstituted C₆-C₂₂ aryl, or a substituted or unsubstituted C₅-C₂₂ heteroaryl; each of R¹¹ and R¹² is independently a hydrogen atom, a linear or branched C₁-C₄ alkyl, a partially halogen substituted or fully halogen substituted C₁-C₄alkyl, a C₅-C₁₂ cycloalkyl, a C₆-C₁₈ aryl, a C₅-C₁₈ heteroaryl group, a C₁-C₄ alkoxy group or a halogen atom; Ar₁ and Ar₂ are each independently a divalent aromatic, aliphatic, or heterocyclic group, or mixtures thereof; Ar₁₁ and A₁₂ are a divalent aromatic, aliphatic, or heterocyclic group or a siloxane group; E is an end-capping group; n₁ is an integer from 5 to 200; n₃ is an integer from 0 to 200; n₅ is an integer from 0 to 200; n₂ is an integer from 5 to 200 and n₄ is an integer from 0 to 200.

17. The photosensitive composition of claim 3, wherein the composition is substantially fluorine-free.

18. A photosensitive composition comprising the following components: at least one polymer of claim 1, at least one sensitizer, at least one adhesion promoter, at least one surfactant, at least one solvent, at least one corrosion inhibitor, at least one plasticizer, and at least one additive, wherein each component independently is substantially fluorine free.
